(19) United States
(12) Patent Application Publication
(10) Pub. No.: US 2004/0063263 A1
(43) Pub. Date: Apr. 1, 2004

(54) Manufacturing method of semiconductor devices

(76) Inventors: Norio Suzuki, Mito (JP); Atsuyoshi Koike, Kunitachi (JP); Shinji Nishihara, Kokubunji (JP); Hirohiko Yamamoto, Hachioji (JP); Kazunori Nemoto, Akishima (JP); Tadashi Suzuki, Higashimurayama (JP); Michimasa Funabashi, Hachioji (JP); Takeshi Kato, Koganei (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/673,214

(22) Filed: Sep. 30, 2003

(30) Foreign Application Priority Data
Sep. 30, 2002 (JP) 2002-286897

(51) Int. Cl. H01L 21/336

(52) U.S. Cl. 438/197

(57) ABSTRACT

A silicon oxide film is formed on the back side of a semiconductor substrate by using a CVD apparatus of a single wafer processing type, with a silicon oxide film deposited on the upper part of trenches on the semiconductor substrate placed downward, to form element isolation comprising the silicon oxide film, and then a MISFET is formed. As a result, even in a manufacturing process using mainly the single wafer processing, in which a film is not formed or hardly formed on the back side of the semiconductor substrate, deterioration of a gate insulating film due to charging-up of the semiconductor substrate, which occurs at the time of plasma processing, for example, at the time of forming a gate electrode or ashing of a resist film, can be prevented, and contamination of the back side of the semiconductor substrate can be prevented. Further, by performing lift-off cleaning which slightly etches the silicon oxide film, the cleaning efficiency can be improved.

### TECHNICAL FIELD OF THE INVENTION

The present invention relates to a manufacturing method of semiconductor devices, and more specifically, relates to an effective technique to be applied to semiconductor devices formed by single wafer processing.

### BACKGROUND OF THE INVENTION

In the case of mass production represented by a general purpose DRAM and the like, a batch processing method for batch-processing a plurality of semiconductor wafers accounts for a large proportion in the manufacturing process of semiconductor devices. Representative steps for performing the batch processing include a heat treatment step, a film forming step and a cleaning step. In these steps, such apparatus is used that can process a plurality of semiconductor wafers simultaneously.

On the other hand, in the manufacturing process of semiconductor devices in which emphasis is placed on the uniformity and controllability of processing, so-called single wafer processing is performed, in which processing is performed for a unit of one semiconductor wafer. A typical example of the single wafer processing is a dry etching step for forming contact holes and through holes.

In a series of manufacturing processes of semiconductor devices, the respective advantages of the single wafer processing and the batch processing are used, and these processing is combined together.

In the semiconductor wafer used for manufacturing the semiconductor device, a face (back side) opposite to a face (surface) on which an element is formed may be processed. For example, the processing is disclosed in Patent Documents 1 to 4 described below.

In Patent Document 1 (Japanese Patent Application Laid-Open No. 59-27529), there is disclosed a manufacturing method of wafers for semiconductor devices, in which before mirror-finishing the surface of the semiconductor wafer, a nitride film is provided on the back side.

In Patent Document 2 (Japanese Patent Application Laid-Open No. 6-275536), there is disclosed a technique in which an oxide film 15 is formed on the back side 13 of a vapor growth plane 12 of a wafer 11, and then a metal film 17 is formed on the vapor growth plane 12, to obtain a metal film 17 with uniform film quality and film thickness on the vapor growth plane 12, while preventing contamination of the wafer 11 and the device due to generation of particles.

In Patent Document 3 (Japanese Patent Application Laid-Open No. 8-111409), there is disclosed a technique in which an oxide film 1a of a semiconductor wafer material is formed on the back side of a semiconductor wafer 1 before the first film forming by the CVD method is performed on the surface of the semiconductor wafer 1, and this oxide film is allowed to remain as it is at least until finishing the last film forming step by the CVD method, thereby performing uniform film forming and processing, while suppressing bending of the semiconductor wafer as much as possible in the heating step of the semiconductor wafer, such as a CVD step.

In Patent Document 4 (Japanese Patent Application Laid-Open No. 2000-21778), there is disclosed a technique in which an oxide film is formed on the back side of a silicon wafer to allow epitaxial growth, wherein the oxide film is slightly removed from the edge of the wafer on the back side, to allow the epitaxial growth.

In Patent Document 5 (Japanese Patent Application Laid-Open No. 5-82462), there is disclosed a technique in which, when heat treatment is performed in a manufacturing process of a semiconductor device, in order to avoid substrate contamination at the time of heat treatment, at least the back side of the semiconductor substrate is covered with material (for example, SiC film formed by CVD method or SiC plate individually prepared) wherein the diffusion coefficient of contamination metal is equivalent or small as compared with the case of the semiconductor substrate and with the silicon nitride film.

However, according to these documents, in a series of manufacturing processes of semiconductor devices, problems in the single wafer processing as described below have not been mentioned.

### SUMMARY OF THE INVENTION

In the new technology field such as multimedia and information communication, an LSI (system LSI) having a system-on-chip structure is realized, in which a microcomputer, a DRAM, an ASIC (Application Specific Integrated Circuit), a flash memory and the like are integrated in one chip, thereby advancing speed-up of data transfer rate, space-saving (improvement in packaging density), and low power consumption.

For the manufacturing of such a system LSI, a wafer having a large diameter, specifically, a semiconductor wafer (Si wafer) having a diameter of 300 mmφ (a diameter of 300 mm±0.2 mm) is employed.

Also in the manufacturing line of semiconductor devices, using a semiconductor wafer having a diameter of 300 mmφ, it is possible to combine the single wafer processing and the batch processing.

However, in the case of job shop type production such as the system LSI, it is effective to process the whole steps of the manufacturing process by the single wafer processing, using a wafer having a large diameter, since the turn around time (TAT) can be reduced. TAT refers to the period since having received an order, through manufacturing in a factory, until the product is delivered to a customer.

For example, in order to accommodate a plurality of wafers having a large diameter, the processing chamber should be large, and it takes time until the inside temperature and pressure are adjusted to the state appropriate for processing.

Further, the same period of time is required for processing one lot (unit number of sheets) or a few numbers of sheets such as two or three, and hence the productivity decreases.

Particularly, in the case of job shop type production such as the system LSI, with diversification of demands, it is not effective to prepare the processor for each processing of the single wafer processing and the batch processing, in view of securing a space for the apparatus and investment in plant and equipment.

Therefore, the present inventors have studied to process a semiconductor wafer having a diameter of 300 mmφ in a manufacturing line in which the single wafer processing is used for the whole steps (particularly, heat treatment step, CVD step and cleaning step).

However, when a semiconductor element is formed by using the single wafer processing in the whole process, problems such as contamination on the back side of the semiconductor wafer, and deterioration in resisting pressure of a gate insulating film of an MISFET (Metal Insulator Semiconductor Field Effect Transistor) have become known.

That is, in the case of the single wafer processing, various films are not formed on the back side of the semiconductor wafer during the manufacturing process, thereby exposing the back side (Si). Particularly, the semiconductor wafer having a diameter of 300 mmφ is polished on the both surfaces to improve the flatness. During the manufacturing process, the wafer is placed on a support (susceptor) of various kinds of semiconductor manufacturing apparatus, so that the back side of the wafer abuts against the upper face of the susceptor. Specifically, an electrostatic chuck mechanism is provided on the susceptor, and the wafer is held on the upper face of the susceptor. Therefore, an insulating film or the like is not formed on the back side of the wafer, and hence the back side (Si) is exposed. Since this Si plane is hydrophobic, material (particles) is likely to adhere, and hard to be removed. This material becomes a contamination source on the wafer surface (main plane on which the element is formed), thereby causing a decrease in the yield of the LSI production.

In the system LSI, the gate insulating film of the MISFET is constituted of two or three kinds of film thickness, and the thickness of a thin gate insulting film is about 2 to 3 nm. There is a problem in that such a thin gate insulating film may be broken due to the electric charge accumulated on the semiconductor wafer during the manufacturing process.

It is an object of the present invention to reduce contaminant in the manufacturing process of semiconductor devices.

It is another object of the present invention to improve a resisting pressure of a gate insulating film of the MISFET.

It is another object of the present invention to improve the characteristic of a semiconductor device, particularly, a semiconductor device manufactured by using a semiconductor wafer having a large diameter, or a semiconductor device formed in a manufacturing process composed mainly of the single wafer processing.

The above objects and novel features of the present invention will become obvious from the description in this specification and the accompanying drawings.

The outline of the representative inventions disclosed in this application will be briefly described below.

The manufacturing method of the semiconductor device of the present invention has (a) a step of preparing a semiconductor wafer having a first principal plane on which an element is formed, and a second principal plane opposite to the first principal plane, (b) a step of forming a protective film only on the second principal plane of the semiconductor wafer, (c) a step of forming a gate insulating film on the first principal plane, after the step (b), and (d) a step of forming a conductor layer on the gate insulating film.

### BRIEF DESCRIPTIONS OF THE DRAWINGS

FIG. 1 is a sectional view of the main part of a semiconductor substrate, illustrating a manufacturing method of a semiconductor device according to a first embodiment of the present invention;

FIG. 2 is a sectional view of the main part of the semiconductor substrate, illustrating the manufacturing method of the semiconductor device according to the first embodiment of the present invention;

FIG. 3 is a sectional view of the main part of the semiconductor substrate, illustrating the manufacturing method of the semiconductor device according to the first embodiment of the present invention;

FIG. 4 is a sectional view of the main part of the semiconductor substrate, illustrating the manufacturing method of the semiconductor device according to the first embodiment of the present invention;

FIG. 5 is a sectional view of the main part of the semiconductor substrate, illustrating the manufacturing method of the semiconductor device according to the first embodiment of the present invention;

FIG. 6 is a sectional view of the main part of the semiconductor substrate, illustrating the manufacturing method of the semiconductor device according to the first embodiment of the present invention;

FIG. 7 is a sectional view of the main part of the semiconductor substrate, illustrating the manufacturing method of the semiconductor device according to the first embodiment of the present invention;

FIG. 8 is a sectional view of the main part of the semiconductor substrate, illustrating the manufacturing method of the semiconductor device according to the first embodiment of the present invention;

FIG. 9 is a sectional view of the main part of the semiconductor substrate, illustrating the manufacturing method of the semiconductor device according to the first embodiment of the present invention;

FIG. 10 is a sectional view of the main part of the semiconductor substrate, illustrating the manufacturing method of the semiconductor device according to the first embodiment of the present invention;

FIG. 11 is a sectional view of the main part of the semiconductor substrate, illustrating the manufacturing method of the semiconductor device according to the first embodiment of the present invention;

FIG. 12 is a sectional view of the main part of the semiconductor substrate, illustrating the manufacturing method of the semiconductor device according to the first embodiment of the present invention;

FIG. 13 is a sectional view of the main part of the semiconductor substrate, illustrating the manufacturing method of the semiconductor device according to the first embodiment of the present invention;

FIG. 14 is a sectional view of the main part of the semiconductor substrate, illustrating the manufacturing method of the semiconductor device according to the first embodiment of the present invention;

FIG. 15 is a sectional view of the main part of the semiconductor substrate, illustrating the manufacturing method of the semiconductor device according to the first embodiment of the present invention;

FIG. 16 is a sectional view of the main part of the semiconductor substrate, illustrating the manufacturing method of the semiconductor device according to the first embodiment of the present invention;

FIG. 17 is a sectional view of the main part of the semiconductor substrate, illustrating the manufacturing method of the semiconductor device according to the first embodiment of the present invention;

FIG. 18 is a sectional view of the main part of the semiconductor substrate, illustrating the manufacturing method of the semiconductor device according to the first embodiment of the present invention;

FIG. 19 is a sectional view of the main part of the semiconductor substrate, illustrating the manufacturing method of the semiconductor device according to a second embodiment of the present invention;

FIG. 20 is a sectional view of the main part of the semiconductor substrate, illustrating the manufacturing method of the semiconductor device according to the second embodiment of the present invention;

FIG. 21 is a sectional view of the main part of the semiconductor substrate, illustrating the manufacturing method of the semiconductor device according to a third embodiment of the present invention;

FIG. 22 is a sectional view of the main part of the semiconductor substrate, illustrating the manufacturing method of the semiconductor device according to the third embodiment of the present invention;

FIG. 23 is a sectional view of the main part of the semiconductor substrate, illustrating the manufacturing method of the semiconductor device according to the third embodiment of the present invention;

FIG. 24 is a sectional view of the main part of the semiconductor substrate, illustrating the manufacturing method of the semiconductor device according to the third embodiment of the present invention;

FIG. 25 is a sectional view of the main part of the semiconductor substrate, illustrating the manufacturing method of the semiconductor device according to the third embodiment of the present invention;

FIG. 26 is a sectional view of the main part of the semiconductor substrate, illustrating the manufacturing method of the semiconductor device according to the third embodiment of the present invention;

FIG. 27 is a sectional view of the main part of the semiconductor substrate, illustrating the manufacturing method of the semiconductor device according to the third embodiment of the present invention;

FIG. 28 is a sectional view of the main part of the semiconductor substrate, illustrating the manufacturing method of the semiconductor device according to the third embodiment of the present invention;

FIG. 29 is a sectional view of the main part of the semiconductor substrate, illustrating the manufacturing method of the semiconductor device according to the third embodiment of the present invention;

FIG. 30 is a sectional view of the main part of the semiconductor substrate, illustrating the manufacturing method of the semiconductor device according to the third embodiment of the present invention;

FIG. 31 is a sectional view of the main part of the semiconductor substrate, illustrating the manufacturing method of the semiconductor device according to the third embodiment of the present invention;

FIG. 32 is a sectional view of the main part of the semiconductor substrate, illustrating the manufacturing method of the semiconductor device according to the third embodiment of the present invention;

FIG. 33 is a sectional view of the main part of the semiconductor substrate, illustrating the manufacturing method of the semiconductor device according to the third embodiment of the present invention;

FIG. 34 is a sectional view of the main part of the semiconductor substrate, illustrating the manufacturing method of the semiconductor device according to the third embodiment of the present invention;

FIG. 35 is a sectional view of the main part of the semiconductor substrate, illustrating the manufacturing method of the semiconductor device according to the third embodiment of the present invention;

FIG. 36 is a sectional view of the main part of the semiconductor substrate, illustrating the manufacturing method of the semiconductor device according to the third embodiment of the present invention;

FIG. 37 is a sectional view of the main part of the semiconductor substrate, illustrating the manufacturing method of the semiconductor device according to the third embodiment of the present invention;

FIG. 38 is a sectional view of the main part of the semiconductor substrate, illustrating the manufacturing method of the semiconductor device according to the third embodiment of the present invention;

FIG. 39 is a sectional view of the main part of the semiconductor substrate, illustrating the manufacturing method of the semiconductor device according to a fourth embodiment of the present invention;

FIG. 40 is a sectional view of the main part of the semiconductor substrate, illustrating the manufacturing method of the semiconductor device according to the fourth embodiment of the present invention;

FIG. 41 is a sectional view of the main part of the semiconductor substrate, illustrating the manufacturing method of the semiconductor device according to the fourth embodiment of the present invention;

FIG. 42 is a sectional view of the main part of the semiconductor substrate, illustrating the manufacturing method of the semiconductor device according to the fourth embodiment of the present invention;

FIG. 43 is a sectional view of the main part of the semiconductor substrate, illustrating the manufacturing method of the semiconductor device according to the fourth embodiment of the present invention;

FIG. 44 is a sectional view of the main part of the semiconductor substrate, illustrating the manufacturing method of the semiconductor device according to the fourth embodiment of the present invention;

FIG. 45 is a sectional view of the main part of the semiconductor substrate, illustrating the manufacturing method of the semiconductor device according to the fourth embodiment of the present invention;

FIG. 46 is a sectional view of the main part of the semiconductor substrate, illustrating the manufacturing method of the semiconductor device according to the fourth embodiment of the present invention;

FIG. 47 is a sectional view of the main part of the semiconductor substrate, illustrating the manufacturing method of the semiconductor device according to the fourth embodiment of the present invention;

FIG. 48 is a sectional view of the main part of the semiconductor substrate, illustrating the manufacturing method of the semiconductor device according to the fourth embodiment of the present invention;

FIG. 49 is a sectional view of the main part of the semiconductor substrate, illustrating the manufacturing method of the semiconductor device according to the fourth embodiment of the present invention;

FIG. 50 is a sectional view of the main part of the semiconductor substrate, illustrating the manufacturing method of the semiconductor device according to the fourth embodiment of the present invention;

FIG. 51 is a sectional view of the main part of the semiconductor substrate, illustrating the manufacturing method of the semiconductor device according to the fourth embodiment of the present invention;

FIG. 52 is a sectional view of the main part of the semiconductor substrate, illustrating the manufacturing method of the semiconductor device according to the fourth embodiment of the present invention;

FIG. 53 is a perspective view showing a semiconductor wafer used in the manufacturing method of the semiconductor device according to the embodiments of the present invention;

FIG. 54 is a sectional view schematically expressing the apparatus and the processing method used in the manufacturing method of the semiconductor device according to the embodiments of the present invention;

FIG. 55A is a sectional view schematically expressing the apparatus and the processing method used in the manufacturing method of the semiconductor device according to the embodiments of the present invention;

FIG. 55B is a sectional view schematically expressing the apparatus and the processing method used in the manufacturing method of the semiconductor device according to the embodiments of the present invention;

FIG. 55C is a sectional view schematically expressing the apparatus and the processing method used in the manufacturing method of the semiconductor device according to the embodiments of the present invention;

FIG. 55D is a sectional view schematically expressing the apparatus and the processing method used in the manufacturing method of the semiconductor device according to the embodiments of the present invention; and

FIG. 56 is a sectional view schematically expressing a processor and a processing method of a batch type.

### DESCRIPTION OF THE PREFERRED EMBODIMENTS

Embodiments of the present invention will be described in detail with reference to the drawings, wherein like reference signs refer to like members having the same function throughout the various figures, and the explanation thereof is omitted.

(First Embodiment)

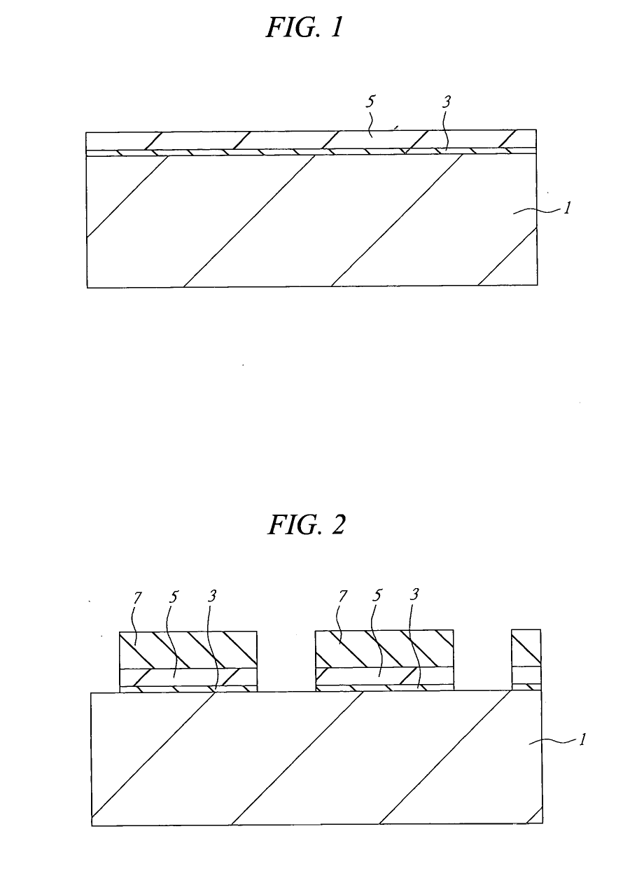

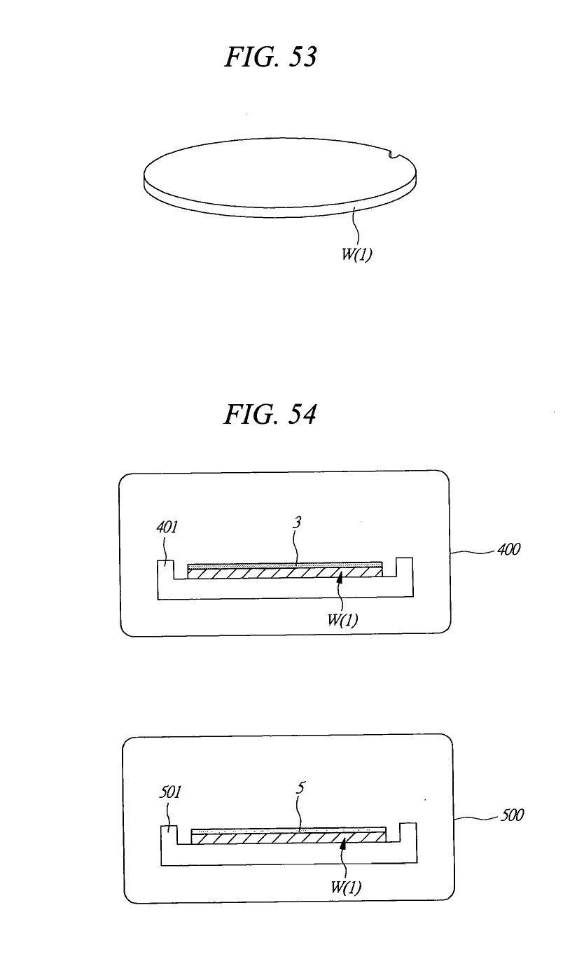

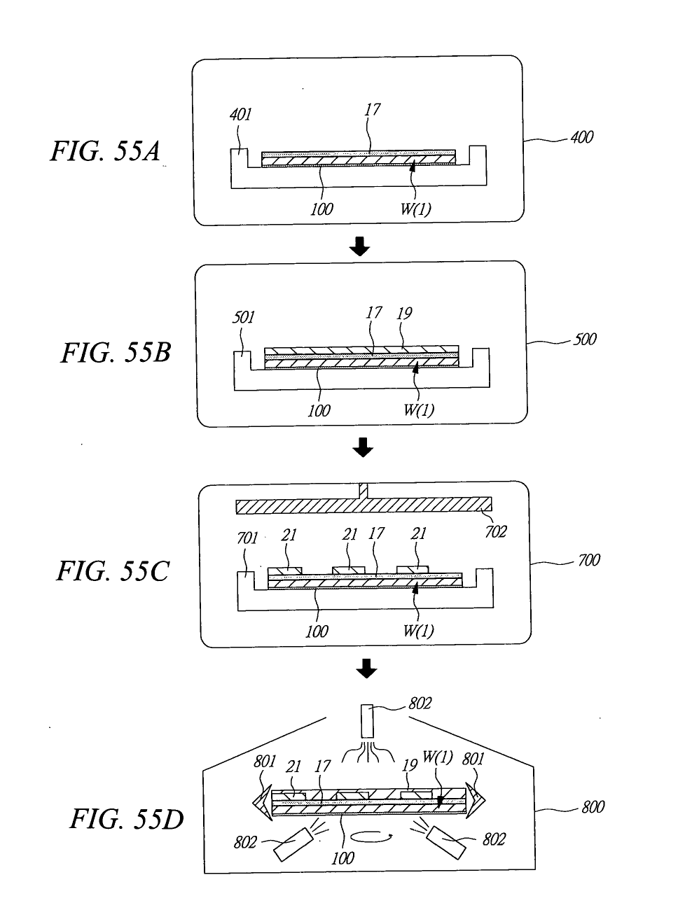

FIGS. 1 to 18 are sectional views of the main part of a semiconductor substrate, illustrating a manufacturing method of a semiconductor device according to the first embodiment of the present invention. FIG. 53 is a perspective view showing a semiconductor wafer used in the manufacturing method of the semiconductor device according to the embodiment. FIGS. 54 and 55 are sectional views schematically expressing the apparatus and the processing method used in the manufacturing method of the semiconductor device according to the embodiment.

The manufacturing method of the semiconductor device according to the embodiment will be described in order of step.

At first, a semiconductor wafer having a diameter of about 300 mm (300±0.2 mm (hereinafter referred to as “having a diameter of 300 mmφ”) as shown in FIG. 54 is prepared. This semiconductor wafer W comprises, for example, a P-type single crystal silicon, and the surface and the back side thereof are mirror-finished.

The mirror finishing is performed by supplying an abrasive to the both faces (the surface and the back side) of, for example, a rotating semiconductor wafer, and pressing a polishing pad against the both faces from above and below (double side polishing). In this manner, by polishing the surface and the back side simultaneously, the flatness can be improved, without causing inclination of the wafer, which occurs when only one side of the wafer that is adhered onto the polishing plate is polished.

The surface and the back side of the semiconductor wafer have a brightness of about 60 to 100%, and at least the surface of the semiconductor wafer preferably has a brightness of 80% or more. For example, the brightness refers to a reflectance ratio when light is allowed to enter into the wafer plane at an incident angle of 60 degrees.

The semiconductor wafer may be polished to some extent by the double side polishing, and thereafter, only the surface (the side where the semiconductor element is formed) may be further polished, to improve the brightness and flatness. Thus, by performing two stage polishing, the throughput of the semiconductor wafer production can be improved, and the cost can be reduced.

In this manner, a semiconductor wafer W (semiconductor substrate 1) comprising a P-type single crystal silicon, whose both faces are mirror-finished, is prepared, to manufacture a semiconductor element such as the MISFET according to the above described process. In this embodiment, there is used a manufacturing line in which the whole steps (heat treatment, CVD, cleaning, sputtering and etching) are single wafer processing type, to form the semiconductor element.

At first, element isolation is formed. In order to form the element isolation, for example, as shown in FIG. 1, a pad oxide film 3 is formed on the semiconductor substrate 1 by thermal oxidation, and then a silicon nitride film 5 is formed on the pad oxide film 3 by a Chemical Vapor Deposition (CVD) method.

Here, thermal oxidation is performed, as shown in the upper diagram in FIG. 54, by using a thermal oxidation apparatus 400 for the single wafer processing. The single wafer processing refers to a method for processing the semiconductor wafer one by one. In the single wafer processing, as shown in the figure, the semiconductor wafer W is mounted on a susceptor 401 in the apparatus, and the processing is performed with the whole back side thereof coming in contact with the susceptor. Therefore, the pad oxide film 3 is formed only the surface (the first principal plane) of the semiconductor wafer W.

Film forming of the silicon nitride film 5 by the CVD method is also performed by using a CVD apparatus 500 for the single wafer processing, as shown in the lower diagram in FIG. 54. As shown in this figure, the semiconductor wafer W is mounted on a susceptor 501 in the apparatus, with the whole back side (the second principal plane) coming in contact with the susceptor. Therefore, the silicon nitride film 5 is formed only on the surface of the semiconductor wafer W.

As described above, the processor for the single wafer processing has a feature in that any film is not formed, or unlikely to be formed, on the back side. Even if the whole back side of the semiconductor wafer comes in contact with the susceptor, a thin film or a partial film may be formed on the back side of the semiconductor wafer, due to a gas going around a slight gap. The present invention does not exclude such a case.

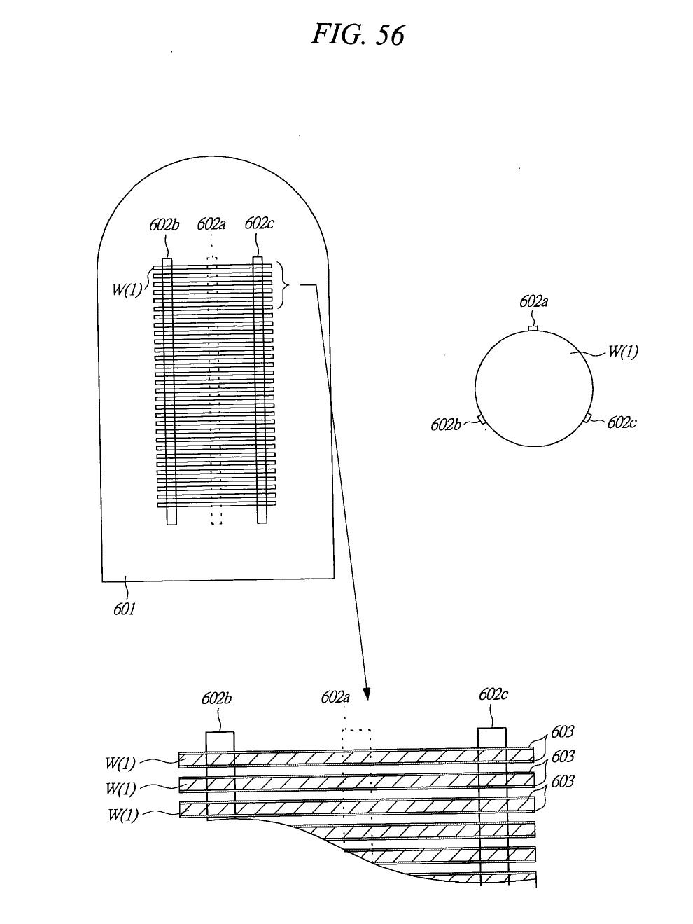

On the other hand, in a processor 601 of a batch type as shown in FIG. 56, a plurality of semiconductor wafers W can be held by wafer holders 602a to 602c, so that not only the surfaces but also the back sides of the semiconductor wafers W can be exposed to the material gas and the oxygen atmosphere, and hence a film 603 is formed also on the back side. The left diagram in FIG. 56 is a longitudinal sectional view showing the main part of the processor 601, and the right diagram is a cross sectional view thereof.

As shown in FIG. 2, a photoresist film (hereinafter simply referred to as a “resist film”) 7 is applied on the upper part of the silicon nitride film 5, and an element isolation region is opened by the photolithography. This resist film 7 is used as a mask to perform etching with respect to the silicon nitride film 5 and the pad oxide film 3.

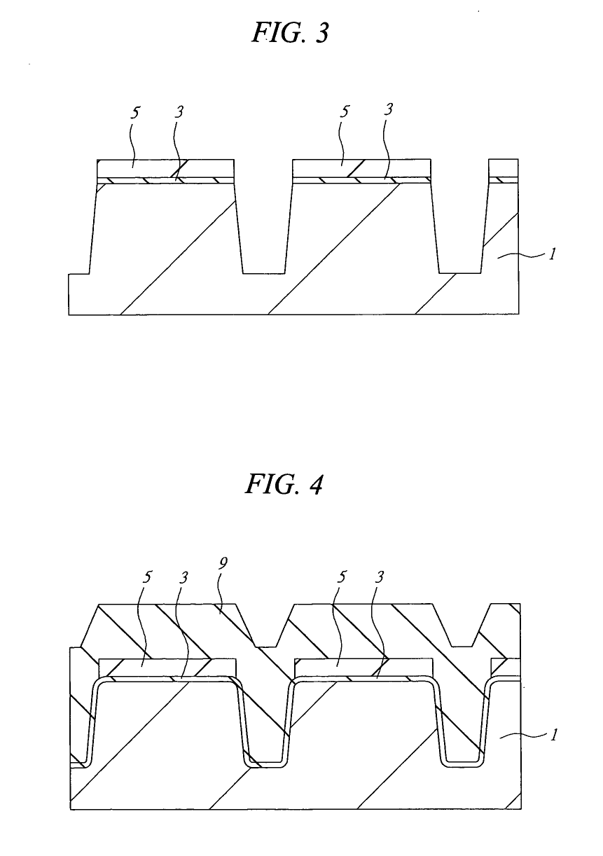

As shown in FIG. 3, the resist film 7 is used as a mask to perform etching with respect to the semiconductor substrate 1, and thereafter, the resist film 7 is removed by ashing (ashing treatment), to form a trench for element isolation.

As shown in FIG. 4, after a thin oxide film is formed on the surface of the trench by thermal oxidation, a silicon oxide film 9 is deposited, in a thickness sufficient to bury the trench, on the semiconductor substrate 1 including the inside of the trench by a high density plasma CVD method. The corner portion of the trench is rounded by the thermal oxidation.

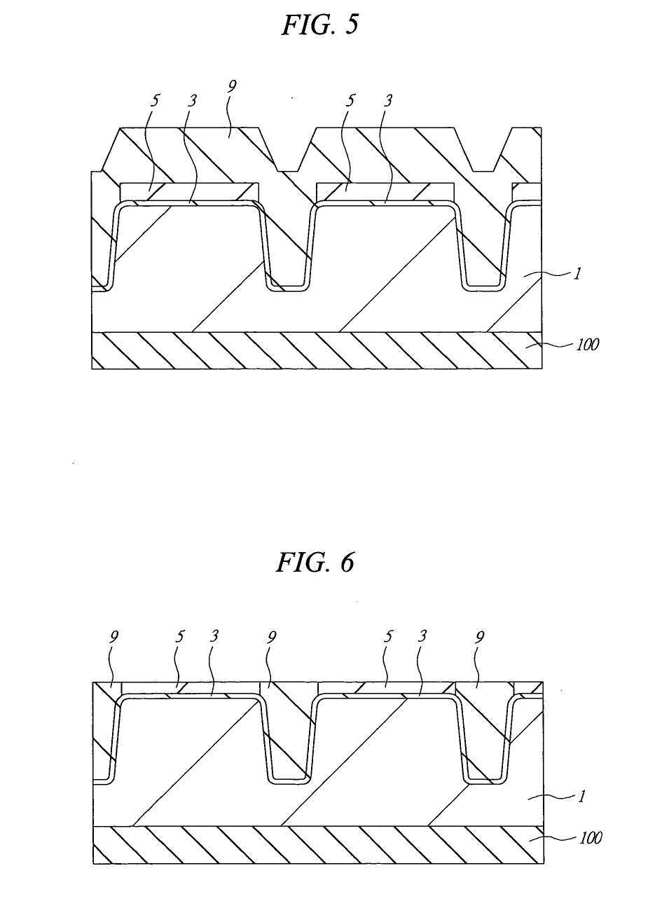

Then, as shown in FIG. 5, an insulating film 100 such as the silicon oxide film is formed by the CVD method on the back side of the semiconductor substrate 1, as a protective film.

This insulating film 100 is formed by using a CVD apparatus 500 for the single wafer processing as shown in the lower diagram in FIG. 54, with the surface of the semiconductor wafer (the silicon oxide film 9) being the lower side.

This silicon oxide film 100 is formed for preventing deterioration in the resisting pressure of the gate insulating film formed afterward.

In other words, the gate insulating film is exposed to a plasma atmosphere at the time of, for example, (1) depositing an insulating film or the like formed by the CVD method, (2) etching the conductive film, being a gate electrode, and (3) ashing the resist film, which has been used as a mask for etching.

There are many kinds of processing using plasma in the CVD, etching and ashing, and at this time, electric charge is likely to be accumulated on the surface of the semiconductor wafer. In other words, the surface of the semiconductor wafer is likely to be charged up. As described above, in the single wafer processing, since a film is unlikely to be formed on the back side of the semiconductor wafer, the semiconductor substrate 1 is brought into direct contact with the susceptor of the processor.

Therefore, the gate insulating film is connected in series between the conductive film, being a gate electrode, and the semiconductor substrate. Particularly, since the gate insulating film is formed thin, it is likely to be affected by the electric charge, and hence the resisting pressure thereof deteriorates.

On the other hand, as in this embodiment, when the silicon oxide film 100 is formed on the back side of the semiconductor substrate, the gate insulating film and the silicon oxide film 100 are connected in series between the conductive film, being a gate electrode, and the semiconductor substrate, and hence, the influence of the electric charge with respect to the gate insulating film can be lowered. That is, a voltage applied to the gate insulating film is reduced. As a result, the resisting pressure of the gate insulating film can be improved.

Further, by forming the silicon oxide film 100 on the back side, a removing factor of the material on the semiconductor wafer is improved.

For example, if the material generated in the manufacturing process of the semiconductor device adheres on the susceptor of various devices, contamination spreads on the back side of all semiconductor wafers in a unit of processing, at the time of sequentially processing the plurality of semiconductor wafers. Moreover, if the semiconductor wafers, whose back sides are contaminated, are carried into the device in the subsequent step and processing is performed, the inside of the processor is contaminated, and contaminant adheres on the semiconductor wafers.

As described above, if the subsequent processing is continued, with the contaminant remaining thereon, the contaminant spreads into the semiconductor elements, thereby deteriorates the characteristic thereof.

Therefore, cleaning of the surfaces and the back sides of the semiconductor wafers is appropriately performed, to avoid such contamination.

At this time, if the insulating film exists on the back side of the semiconductor wafer, the removing factor of the material on the semiconductor wafer is improved.

In other words, since the semiconductor substrate comprising silicon is hydrophobic, material is likely to adhere thereon, and the adhered material (particularly, metal type material) is hard to be removed. On the other hand, the insulating film such as the silicon oxide film formed on the back side of the semiconductor substrate is hydrophilic, in many cases, and the material can be easily removed.

Further, by using a fluorine type cleaning solution, the silicon oxide film formed on the back side of the semiconductor substrate is slightly etched, thereby enabling removal of the material in a lift-off manner.

Further, by forming the silicon oxide film 100 on the back side, metal atoms constituting the material can be prevented from spreading into the semiconductor substrate.

For the protective film to be formed on the back side of the semiconductor substrate, a silicon nitride film or the like may be used, other than the silicon oxide film 100. Alternatively, a laminated film of these may be used. The protective film should have a film thickness such that bending of the semiconductor wafer does not increase, and an increase of the material due to formation of the protective film can be suppressed as much as possible. Moreover, the film thickness thereof should be sufficient for reducing a damage of the semiconductor substrate due to accumulation of electric charge or the like, and exerting an invasion prevention effect and a removal (cleaning) effect of the material. For example, it is considered that a desired thickness is from about 20 to 500 nm. Furthermore, since the membrane stress of the silicon oxide film is smaller than that of the silicon nitride film, by using the silicon oxide film, bending of the semiconductor wafer can be reduced.

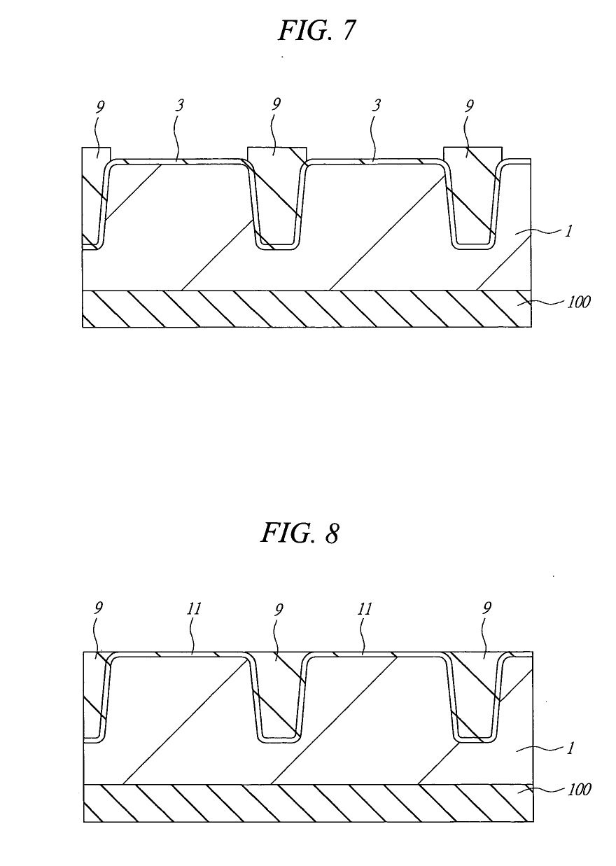

As shown in FIG. 6, the silicon oxide film 9 on the upper part of the trench is polished by a Chemical Mechanical Polishing (CMP) method until the silicon nitride film 5 is exposed. As shown in FIG. 7, the silicon nitride film 5 is then removed.

Subsequently, the surface of the semiconductor substrate 1 is cleaned by wet etching using hydrofluoric acid, and after the pad oxide film 3 is removed, as shown in FIG. 8, a sacrificial oxide film 11 having a thickness of about 11 nm is formed on the surface of the semiconductor substrate 1 by thermal oxidation.

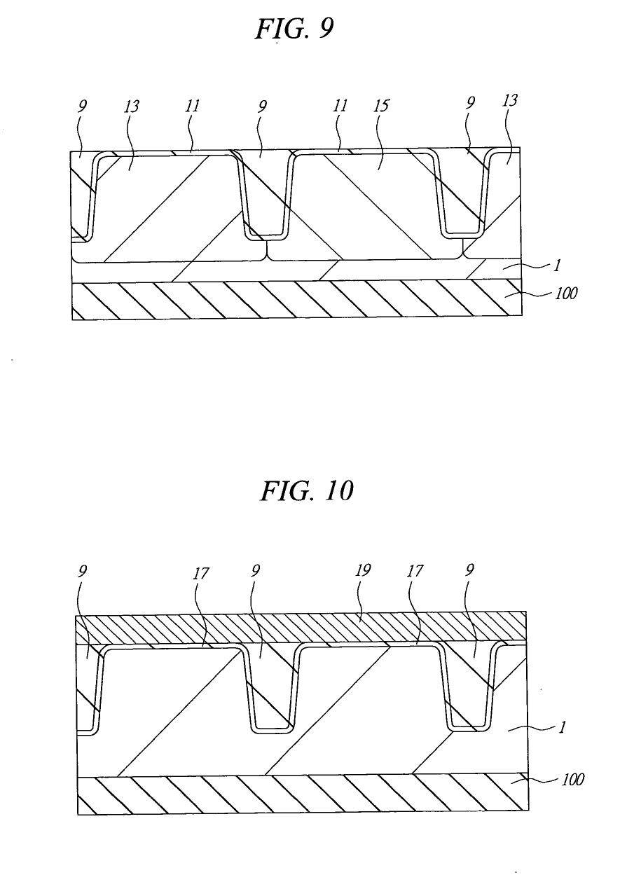

As shown in FIG. 9, a p-channel MISFET forming region is covered with a resist film (not shown), and p-type impurities are ion-implanted into the semiconductor substrate 1. At this time, ion implantation for adjusting a threshold is performed with respect to the surface of a p-type well 13, described later. Subsequently, after having removed the resist film by ashing, an n-channel MISFET forming region is masked with a resist film (not shown), to perform ion implantation of n-type impurities into the semiconductor substrate 1. At this time, ion implantation for adjusting the threshold is performed with respect to the surface of an n-type well 15, described later.

After having removed the resist film by ashing, the impurities are diffused by the subsequent heat treatment, to form the p-type well 13 and the n-type well 15.

After the surface of the semiconductor substrate 1 has been cleaned by wet etching using hydrofluoric acid, a gate insulating film 17 having a thickness of from 2 to 3 nm is formed on the surface of the semiconductor substrate 1. The gate insulating film 17 is formed by using the thermal oxidation apparatus 400 for the single wafer processing, as shown in FIG. 55A, the semiconductor wafer W is mounted on the susceptor 401 in the apparatus, and for example, the processing is performed with the whole back side thereof (silicon oxide film 100) coming in contact with the susceptor. Therefore, the gate insulating film 17 is formed only on the surface of the semiconductor wafer W. After the surface of the semiconductor substrate 1 has undergone thermal oxidation, oxynitride processing may be performed in an NO (nitrogen monoxide) atmosphere, to form the gate insulating film 17. A resistance against hot carrier is improved by the oxynitride processing.

A polysilicon film 19 is deposited on the gate insulating film 17 by the CVD method. This polysilicon film 19 is formed by using the CVD apparatus 500 for the single wafer processing, as shown in FIG. 55B, the semiconductor wafer W is mounted on the susceptor 501 in the apparatus, and for example, the processing is performed with the whole back side thereof coming in contact with the susceptor. Therefore, the polysilicon film 19 is formed only on the surface of the semiconductor wafer W.

N-type impurities such as phosphorus are implanted into the polysilicon film 19 on the p-type well 13, using a resist film (not shown) as a mask. After the resist film has been removed by ashing, p-type impurities such as boron are implanted into the polysilicon film 19 on the n-type well 15, using a resist film (not shown) as a mask.

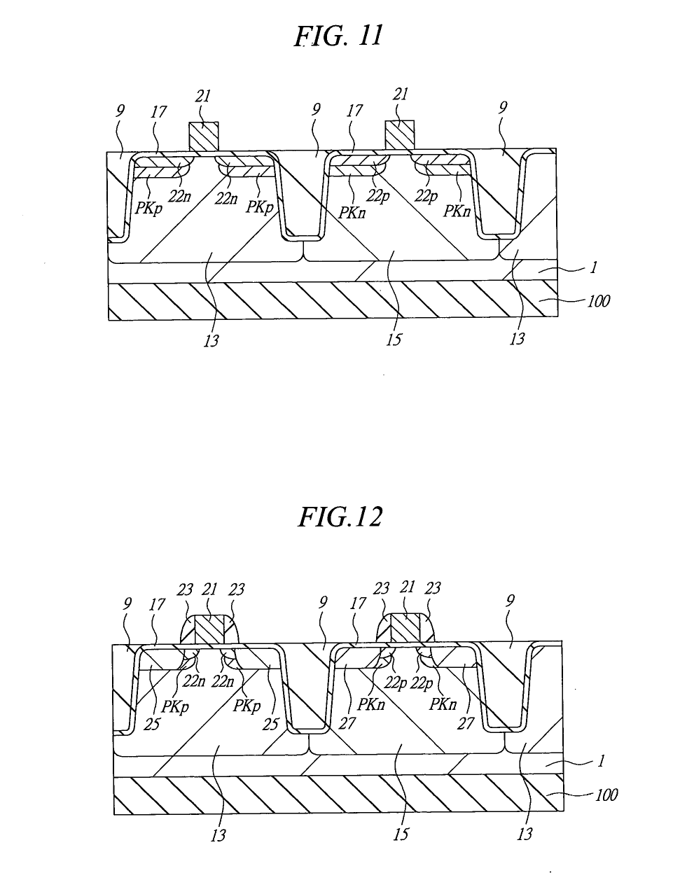

After the resist film has been removed by ashing, as shown in FIG. 11, the polysilicon film 19 is plasma-etched, using a film (not shown) as a mask, to form a gate electrode 21. This plasma etching is performed by using an etching apparatus 700 for the single wafer processing, as shown in FIG. 55C, the semiconductor wafer W is mounted on a susceptor 701 in the apparatus, and for example, the processing is performed with the whole back side thereof coming in contact with the susceptor. Here, reference numeral 702 denotes an electrode.

At this time, plasma is generated inside the etching apparatus 700. According to the embodiment, however, since the silicon oxide film 100 is formed on the back side of the semiconductor substrate, even if electric charge is accumulated on the semiconductor substrate, at the time of plasma etching of the polysilicon film 19, the influence of the electric charge with respect to the gate insulating film 17 can be reduced, thereby improving the resisting pressure of the gate insulating film.

The p-channel MISFET forming region is then covered with a resist film (not shown), and ion implantation of p-type impurities is performed with respect to the semiconductor substrate 1 on the opposite sides of the gate electrode 21 on the p-type well 13. Moreover, ion implantation of n-type impurities is performed with respect to the p-type well 13 on the opposite sides of the gate electrode 21. After having removed the resist film by ashing, the impurities are diffused by heat treatment, to form a p-type pocket ion region PKp and an n⁻-type semiconductor region 22n.

The n-channel MISFET forming region is then covered with a resist film (not shown), and ion implantation of n-type impurities is performed with respect to the semiconductor substrate 1 on the opposite sides of the gate electrode 21 on the n-type well 15. Moreover, ion implantation of p-type impurities is performed with respect to the n-type well 15 on the opposite sides of the gate electrode 21. After having removed the resist film by ashing, the impurities are diffused by heat treatment, to form an n-type pocket ion region PKn and an p⁻-type semiconductor region 22p. The pocket ion regions PKp and PKn are formed for suppressing extension of a depletion layer from the source and drain, and reducing a leak current due to a punchthrough phenomenon.

After having deposited the silicon nitride film 23 on the semiconductor substrate 1 by the CVD method, anisotropic etching is performed, thereby to form a sidewall spacer on the sidewall of the gate electrode 21.

The p-channel MISFET forming region is then covered with a resist film (not shown), and as shown in FIG. 12, n-type impurities are ion-implanted into the p-type well 13. The resist film is removed by ashing, the n-channel MISFET forming region is then covered with a resist film (not shown), and p-type impurities are ion-implanted into the n-type well 15. After removing the resist film by ashing, the impurities are diffused by heat treatment, to form an n⁺-type semiconductor region 25 (source and drain) and a p⁺-type semiconductor region 27 (source and drain).

At the time of ion implantation of impurities and ashing of the resist film, the surface of the semiconductor wafer is charged up, but according to this embodiment, the influence of electric charge with respect to the gate insulating film 17 can be reduced.

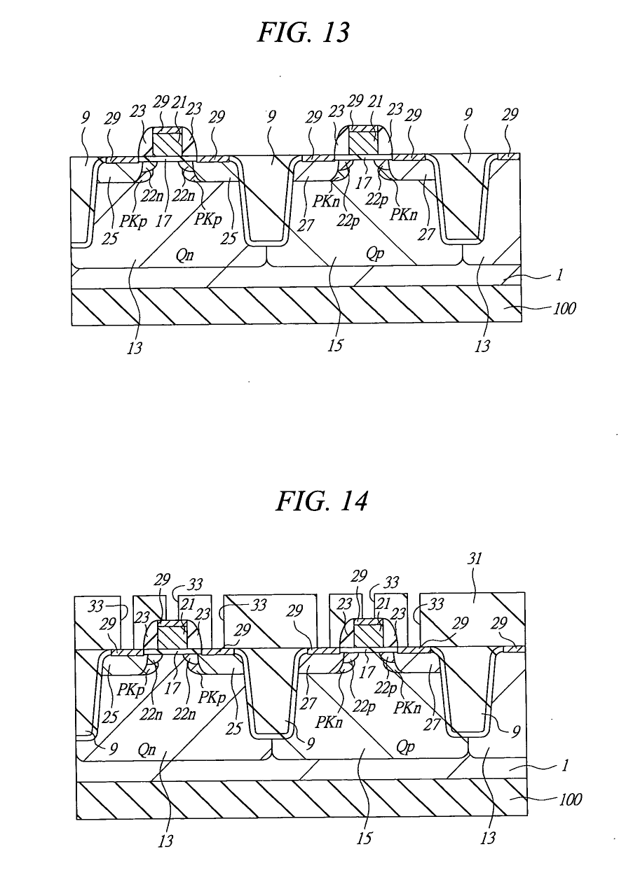

As shown in FIG. 13, a Co (cobalt) film is deposited on the semiconductor substrate 1 by sputtering, and heat treatment at about 500° C. is applied thereto, thereby causing a silicidation reaction at a contact portion between the semiconductor substrate 1 (the n⁺-type semiconductor region 25, the p⁺-type semiconductor region 27 and the like) and the Co film, and a contact portion between the gate electrode 21 and the Co film, to form a cobalt silicide layer 29 on the semiconductor substrate 1 and the gate electrode 21.

Subsequently, the non-reacted Co film is removed by etching, and treatment at about 700° C. is applied thereto, thereby allowing the cobalt silicide layer 29 to remain on the semiconductor substrate 1 and the gate electrode 21. This cobalt silicide layer 29 is formed for decreasing a resistance of the n⁺-type semiconductor region 25, the p⁺-type semiconductor region 27 and the gate electrode G, or reducing the connection resistance.

In the process up to here, an n-channel MISFET Qn and a p-channel MISFET Qp having the source and drain of a Lightly Doped Drain (LDD) structure are formed.

As shown in FIG. 14, a silicon oxide film 31 is deposited on the MISFET Qn and Qp as an interlayer insulating film by the CVD method. This step is performed by using the CVD apparatus for the single wafer processing (see the lower diagram in FIG. 54). Here, the silicon oxide film 31 can be formed by the high-density plasma CVD method. According to this method, etching of the deposited film by the plasma is performed simultaneously with deposition of the film, and hence a film can be formed with good implantation characteristic on a semiconductor substrate having fine irregularities. Further, the flatness on the upper part thereof can be improved.

A resist film (not shown) is formed on the silicon oxide film 31, and the silicon oxide film 31 is etched by using this resist film as a mask, thereby to form contact holes 33 on the n⁺-type semiconductor region 25, the p⁺-type semiconductor region 27 and the gate electrode 21.

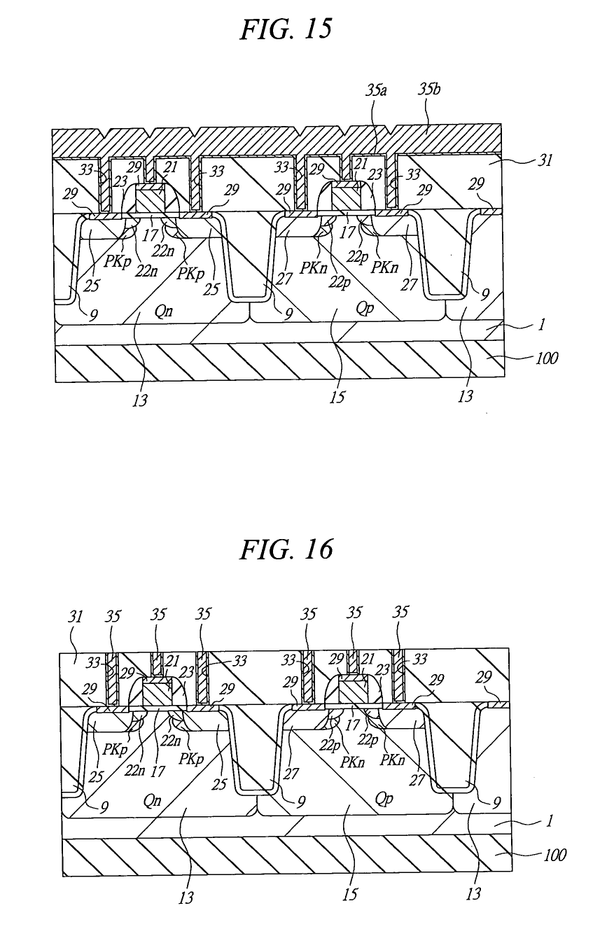

After having removed the resist film by ashing, as shown in FIG. 15, a thin TiN film (titanium nitride thin film) 35a is deposited on the silicon oxide film 31 including the contact holes 33 by sputtering. This TiN film serves as a barrier metal film, which prevents an undesirable reaction layer from being formed due to a contact between W (tungsten) and Si (silicon substrate), described later. The single wafer processing apparatus is used for the film forming by sputtering.

For example, after forming the TiN film 35a, the surface and the back side of the semiconductor substrate are cleaned. This cleaning is performed by using a cleaning apparatus 800 for the single wafer processing, as shown in FIG. 55D, and the semiconductor wafer W is fixed by a clamp 801 on the outer periphery thereof, with the clamp 801 rotated by a rotation mechanism (not shown). Therefore, not only the surface but also the back side of the semiconductor wafer are exposed, and by ejecting a cleaning solution from nozzles 802 located above and below thereof, the surface and the back side of the semiconductor wafer W can be cleaned at the same time. Needless to say, a cleaning apparatus of a type in which the semiconductor wafer is mounted on a plate-like susceptor may be used to clean the surface and the back side separately.

According to this embodiment, since the silicon oxide film 100 is formed on the back side of the semiconductor substrate, the back side of the semiconductor substrate 1 becomes hydrophilic, and hence the adhered material (particularly, metal material) is easily removed. Further, by using a cleaning solution that slightly etches the silicon oxide film 100 formed on the back side of the semiconductor substrate, the material can be removed in a lift-off manner, thereby improving the cleaning efficiency.

On the contrary, when the hydrophobic substrate (Si) is exposed from the back side thereof, material is likely to adhere, and hard to be removed.

Subsequently, for example, a W film 35b is deposited by sputtering, on the TiN film 35a as a conductive film.

As shown in FIG. 16, the W film 35b and the like are polished by the CMP method until the silicon oxide film 31 is exposed, thereby forming plugs 35 comprising the TiN film 35a and the W film 35b in the contact holes 33.

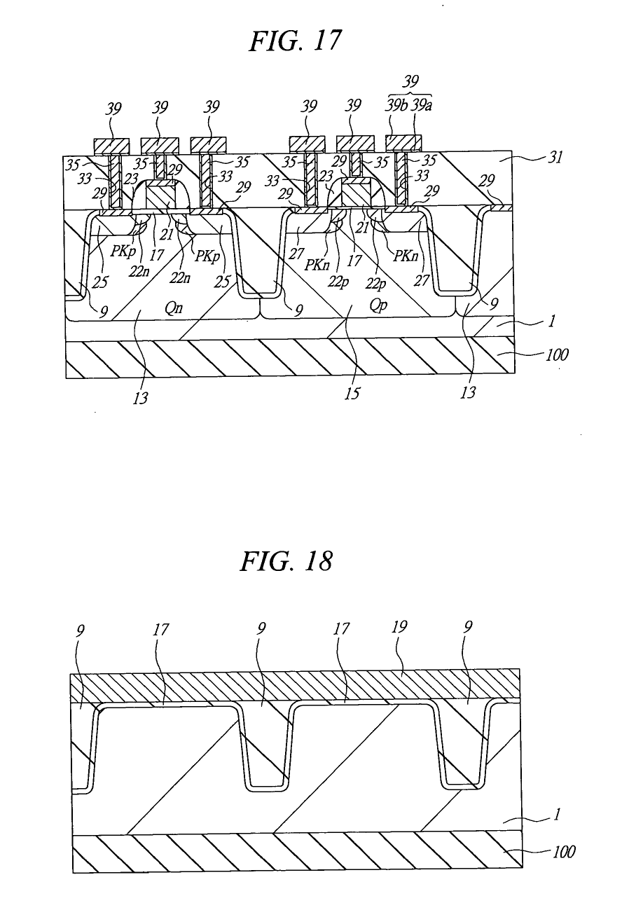

As shown in FIG. 17, thin TiN films 39a are deposited by sputtering on the silicon oxide film 31 and the plugs 35. A W film 39b is then deposited thereon as a conductive film by sputtering. The W film 39b is then patterned into a desired shape, to form a first layer wiring 39. The above described cleaning may be appropriately performed after forming the TiN film 39a.

Thereafter, it is possible to form a multi-layer wiring by repeating the forming steps of the insulating film such as the silicon oxide film, plugs and wiring, on the first layer wiring 39. The forming step will be described in detail in a second embodiment.

In this embodiment, since the silicon oxide film 100 is formed on the back side of the semiconductor substrate, even if electric charge is accumulated on the semiconductor substrate due to the influence of plasma or the like, it can be prevented that the film quality of the gate insulating film deteriorates.

In this embodiment, as the processing for generating plasma, particularly, plasma etching has been described in detail as an example, but the plasma CVD and ashing are also performed by using plasma. At the time of ion (impurities) implantation, electric charge can be also accumulated on the surface of the semiconductor wafer. Further, at the time of depositing a film such as Co film by sputtering, electric charge can be also accumulated on the surface of the semiconductor wafer.

At the time of processing during which electric charge can be accumulated on the surface of the semiconductor wafer, it is prevented that the gate insulating film is charged up, and the resisting pressure of the gate insulating film can be maintained.

According to this embodiment, since the silicon oxide film 100 is formed on the back side of the semiconductor substrate, the back side of the semiconductor substrate becomes hydrophilic, thereby enabling removal of the material in a lift-off manner, and improving the cleaning efficiency.

In this embodiment, cleaning of the TiN film constituting the plug has been described in detail, but cleaning may be performed after forming the polysilicon film 19, and cleaning may be performed after forming not only the conductive film but also the insulating film such as the silicon oxide film.

In this embodiment, after the silicon oxide film 9 for element isolation is deposited, the silicon oxide film 100 is formed on the back side of the semiconductor substrate. However, the forming step of the silicon oxide film 100 is not limited to such time (timing), and may be before or after this step. For example, as shown in FIG. 18, after depositing the polysilicon film 19, the silicon oxide film 100 may be formed on the back side of the semiconductor substrate. Particularly, when a dual gate structure is formed, since two kinds of impurities are implanted in the polysilicon film 19, the resist film ashing step increases. Therefore, the influence of charging up due to the ashing step thereafter can be reduced.

When it is aimed to prevent deterioration of resisting pressure of the gate insulating film, it is effective to form the silicon oxide film 100 before forming the gate insulating film, or between the forming step of the gate insulating film and a step in which the semiconductor substrate may be charged up. Further, when it is aimed to improve the cleaning efficiency, it is desired to form the silicon oxide film 100 before forming a film in which material is likely to be generated.

However, if the silicon oxide film 100 is formed at an early stage in the manufacturing process of the semiconductor element, the both object can be achieved.

Therefore, for example, after deposition of the silicon nitride film 5 (FIG. 1), the silicon oxide film 100 may be formed. However, since this silicon nitride film 5 is an important film for deciding the semiconductor element forming region, in order to deposit the silicon oxide film 100 by putting the surface thereof as a back side, it is necessary to maintain the cleanness in the apparatus and of the susceptor, and to take measures so that the surface of the silicon nitride film 5 is not damaged.

On the other hand, after depositing the silicon oxide film 9 for the element isolation (FIG. 9), the semiconductor element forming region has been already specified, and the surface of the silicon oxide film 9 is removed by the CMP. Therefore, it is not necessary to take measures against the surface contamination.

Therefore, it is considered to be more effective to form the silicon oxide film 100 at such a timing.

(Second Embodiment)

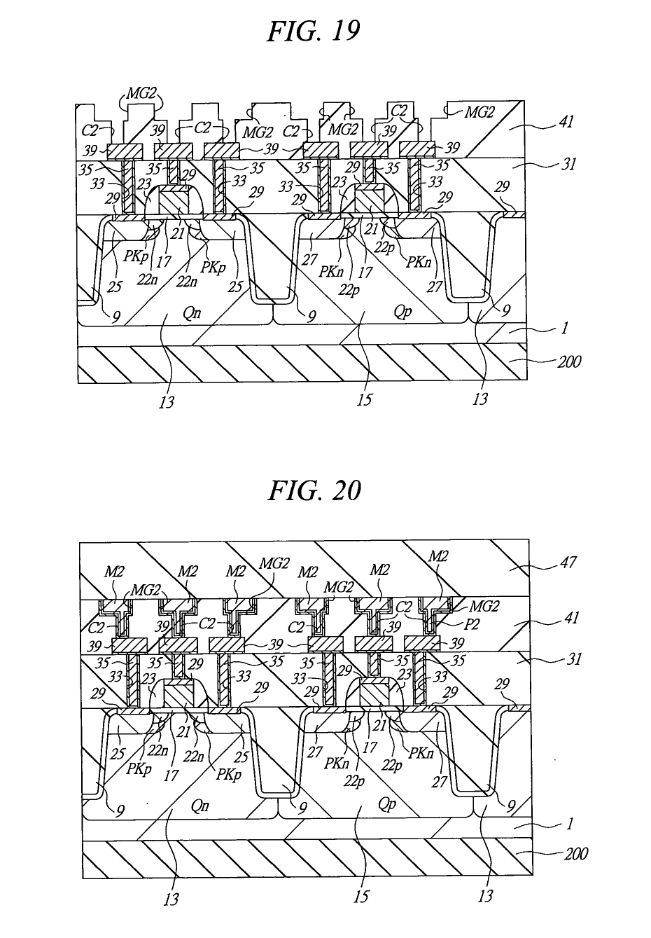

FIG. 19 and FIG. 20 are sectional views of the main part of the semiconductor substrate, illustrating the manufacturing method of the semiconductor device according to the second embodiment.

As shown in FIG. 19, a semiconductor substrate 1 is prepared, on which an n-channel MISFET Qn and a p-channel MISFET Qp having the source and drain of the Lightly Doped Drain (LDD) structure are formed, and a silicon oxide film 31, plugs 35 and a first layer wiring 39 are formed thereon.

This semiconductor substrate 1 has a diameter of about 300 mm, as explained with reference to FIG. 53, and the surface and the back side thereof are mirror-finished. Moreover, the n-channel MISFET Qn, the p-channel MISFET Qp, the silicon oxide film 31, the plugs 35 and the first layer wiring 39 can be formed likewise as in the first embodiment, and hence the detailed explanation thereof is omitted.

An interlayer insulating film 41 is then formed on the silicon oxide film 31 including the first layer wiring 39. This interlayer insulating film 41 comprises a laminated film of, for example, a first silicon nitride film, a first silicon oxide film, a second silicon nitride film and a second silicon oxide film, from the bottom.

For example, a silicon oxide film 200 is formed by the CVD method on the back side of the semiconductor substrate, as an insulating film. As described in the first embodiment, this silicon oxide film 200 is formed by the CVD apparatus of the single wafer processing type, with the surface of the semiconductor wafer placed downward (see the lower diagram in FIG. 54).

A hard mask (not shown) in which a second layer wiring forming region is opened is then formed on the second silicon oxide film, and a resist film (not shown) in which contact hole forming regions are opened is formed on the hard mask. This resist film is used as a mask to etch the interlayer insulating film 41, thereby forming contact holes C2. Thereafter, the resist film is removed by ashing, and the second silicon oxide film and the second silicon nitride film are removed by using the hard mask as a mask, to form wiring trenches MG2. The first and second silicon nitride films serve as an etching stopper.

For example, a thin TiN film is deposited by sputtering on the interlayer insulating film 41 as a barrier film, and a thin Cu (copper) film is deposited thereon as a seed film by sputtering.

A Cu film is then formed on the semiconductor substrate 1 including the wiring trenches MG2 and the inside of the contact holes C2 by an electrolytic plating method. In order to form the Cu film, the substrate 1 is soaked in a plating solution for Cu to fix the seed film to a negative (−) electrode, so that the Cu film is deposited to a degree sufficient for burying the wiring trenches MG2.

The Cu film outside of the wiring trenches MG2 and the contact holes C2 is polished by the CMP method, until the interlayer insulating film 41 is exposed, thereby to form a plug P2 in the contact hole C2 and a second layer wiring M2 in the wiring trenches MG2.

According to this embodiment, since the silicon oxide film 200 is formed on the back side of the semiconductor substrate, before forming the Cu film, the back side of the semiconductor substrate can be prevented from being contaminated due to copper. It can be also prevented that Cu diffuses into the semiconductor substrate. Particularly, Cu is likely to diffuse into the semiconductor substrate (Si), thereby causing deterioration in the characteristics of the semiconductor element and the like.

After such plating processing, cleaning of the back side of the semiconductor wafer described in the first embodiment is performed. However, if a cleaning solution that slightly etches the silicon oxide film 200, even if copper is deposited on the silicon oxide film 200, copper can be removed in a lift-off manner. As a result, the cleaning efficiency can be improved.

Thereafter, by forming an insulating film 47 on the second layer wiring M2, and repeating the forming steps of plugs and wiring, a multi-layer wiring can be formed, but the description and illustration of these forming steps are omitted.

Further, on the uppermost layer wiring, a passivation film comprising a laminated film of a silicon oxide film and a silicon nitride film is formed, and this film is selectively removed to expose a pad. The wafer-form semiconductor substrate is then diced, and the individual chip pad and an external terminal of a mount board are connected by using a bump and a gold wire. The periphery of the chip is sealed by a resin or the like, according to need, thereby the semiconductor device is obtained. However, detailed description and illustration of these forming steps are omitted.

The back side of the semiconductor substrate may be polished to make the substrate thin, before dicing the semiconductor substrate in the wafer form.

In this embodiment, the MISFET is formed as the semiconductor element, but other elements such as bipolar transistor and the like may be formed. Moreover, a copper wiring has been described as an example, but other conductive films, for example, an Al (aluminum) film containing Si, may be used to form wiring. However, copper has a low resistance, and hence by using the copper wiring, high-speed operation of the semiconductor device becomes possible. Furthermore, since copper is likely to diffuse in the semiconductor substrate and the insulator, as described above, this embodiment is effectively used for the copper wiring.

As explained in the first embodiment, after depositing the silicon oxide film 9 for element isolation, if the silicon oxide film 200 is formed on the back side of the semiconductor substrate, even if there is a forming step of the Cu film explained in this embodiment, it can be prevented that the back side of the semiconductor substrate is contaminated by copper, and diffusion of Cu into the semiconductor substrate can be also prevented.

(Third Embodiment)

In the first embodiment, the semiconductor element is formed by using a production line in which the whole steps (heat treatment, CVD, cleaning, sputtering and etching) are the single wafer processing type. However, as described below, the semiconductor element may be formed by using a batch-type heat treatment apparatus and a batch-type CVD apparatus. That is, the semiconductor element may be formed by using a production line in which the batch-type apparatus and the single wafer processing type apparatus are combined.

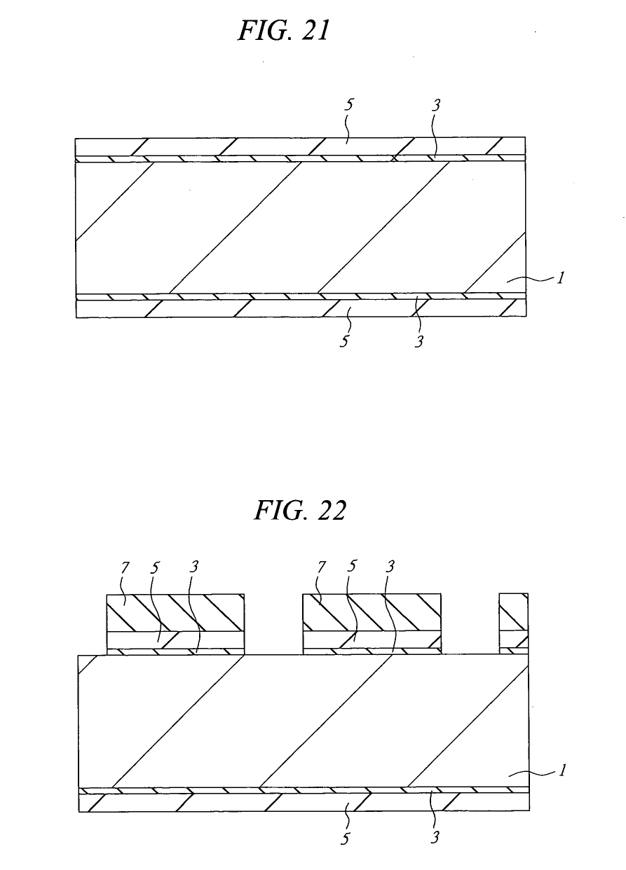

FIGS. 21 to 38 are sectional views of the main part of the semiconductor substrate, illustrating the manufacturing method of the semiconductor device according to the third embodiment. The manufacturing method of the semiconductor device in this embodiment will be described in order of steps. Detailed description for the same steps as in the first embodiment is omitted.

As shown in FIG. 21, a pad oxide film 3 is formed by thermal oxidation on the semiconductor substrate 1. Subsequently, a silicon nitride film 5 is deposited on the pad oxide film 3 by the CVD method.

At this time, the pad oxide film 3 is formed by using a batch-type thermal oxidation apparatus in which the back side of the semiconductor substrate is also exposed to the oxygen atmosphere. As a result, the pad oxide film 3 is formed on both the surface and the back side of the semiconductor wafer W (semiconductor substrate 1).

Further, the silicon nitride film 5 is also formed by using a batch-type CVD apparatus in which the back side of the semiconductor substrate is also exposed to the raw material gas. As a result, the silicon nitride film 5 is formed both on the surface and the back side of the semiconductor wafer W.

As shown in FIG. 22, the silicon nitride film 5 and the pad oxide film 3 are etched by using a resist film 7 above the silicon nitride film 5, in which element isolation regions are opened, as a mask.

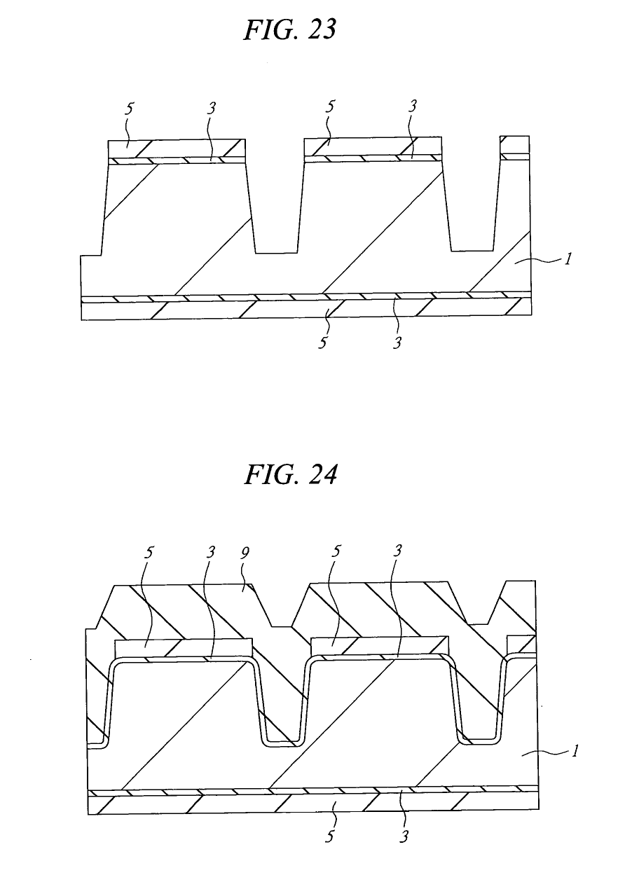

As shown in FIG. 23, trenches for element isolation are formed, and as shown in FIG. 24, after the surfaces of the trenches are subjected to thermal oxidation, a silicon oxide film 9 is deposited on the semiconductor substrate 1 including the inside of the trenches.

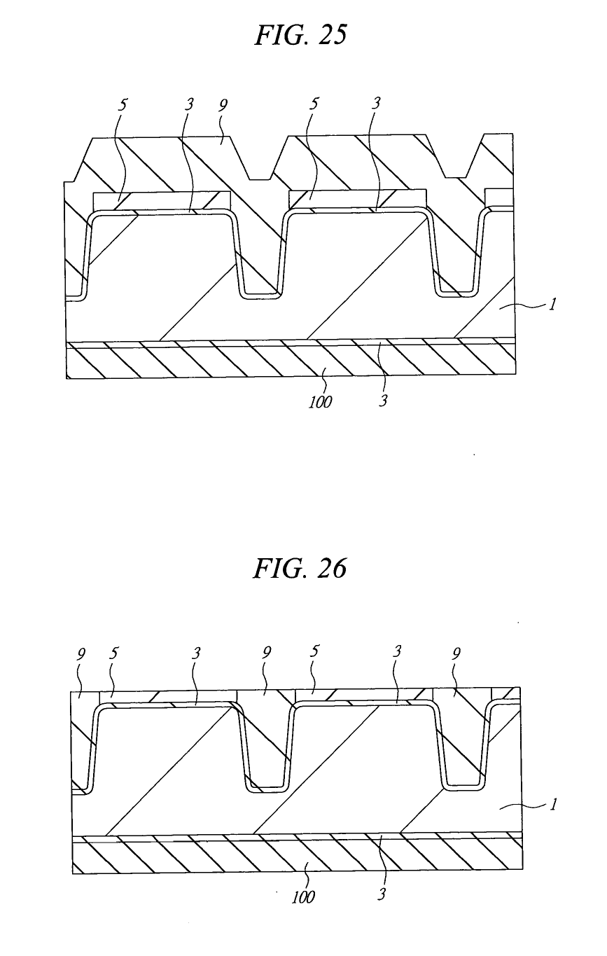

As shown in FIG. 25, the silicon nitride film 5 on the back side of the semiconductor substrate 1 is removed, and for example, a silicon oxide film 100 is formed as an insulating film on the back side of the semiconductor substrate by the CVD method. By removing the silicon nitride film 5, the membrane stress is reduced. The silicon oxide film 100 is formed by using the high density plasma CVD apparatus of the single wafer processing type, with the surface of the semiconductor wafer placed downward.

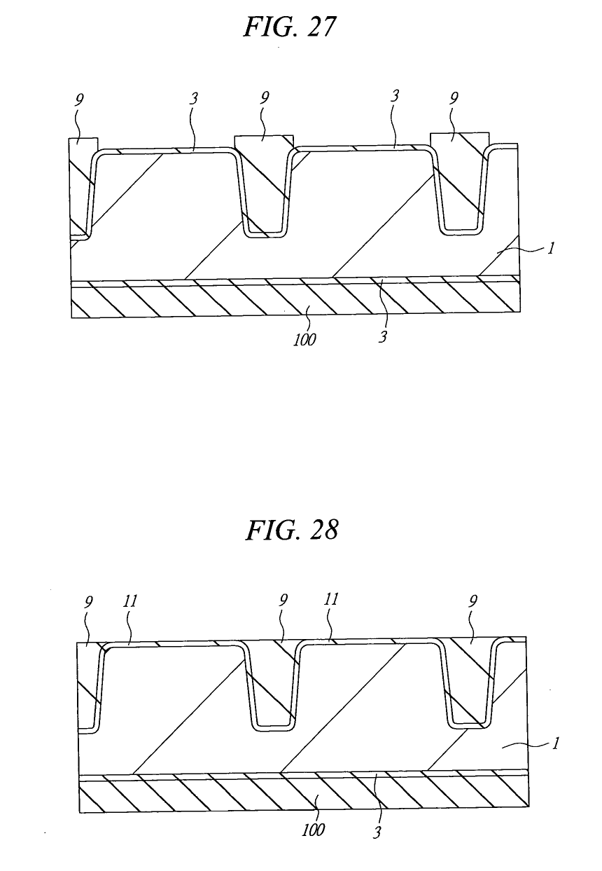

As shown in FIG. 26, the silicon oxide film 9 on the trenches is removed by polishing using the CMP method, and then, as shown in FIG. 27, the silicon nitride film 5 is also removed.

As shown in FIG. 28, after removing the pad oxide film 3, a sacrificial oxide film 11 having a film thickness of about 11 nm is formed on the surface of the semiconductor substrate 1 by thermal oxidation.

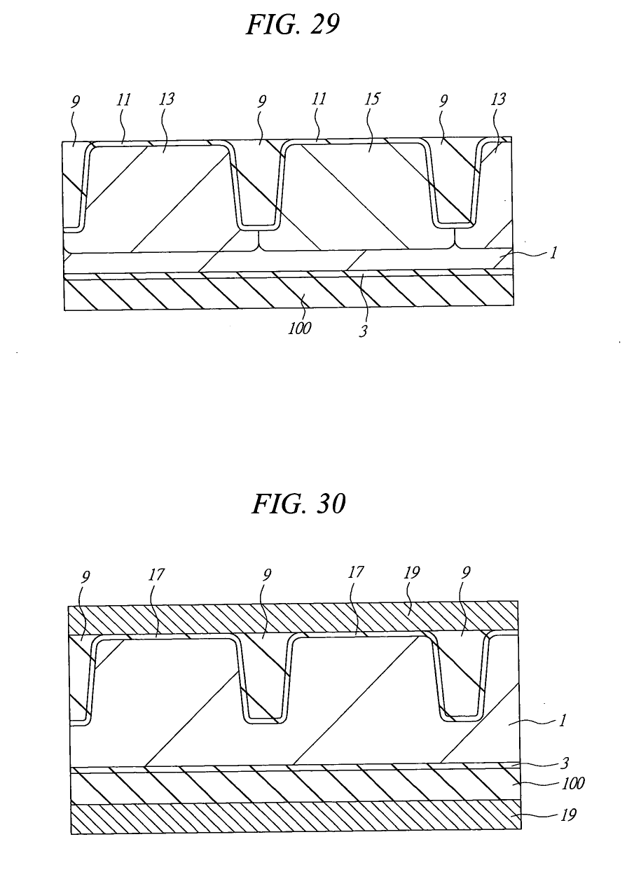

As shown in FIG. 29, ion implantation for adjusting a threshold is performed, and then a p-type well 13 and an n-type well 15 are formed.

Thereafter, the surface of the semiconductor substrate 1 is cleaned, and as shown in FIG. 30, a gate insulating film 17 is formed on the surface of the semiconductor substrate 1, by thermal oxidation. This gate insulating film 17 is formed by using a batch-type thermal oxidation apparatus.

A polysilicon film 19 is deposited on the gate insulating film 17 by the CVD method. This polysilicon film 19 is formed by using a batch-type CVD apparatus, so that the back side thereof is also exposed to the raw material gas atmosphere. As a result, the polysilicon film 19 is formed both on the surface and the back side of the semiconductor wafer W.

N-type impurities such as phosphorus are implanted into the polysilicon film 19 on the p-type well 13, and p-type impurities such as boron are implanted into the polysilicon film 19 on the n-type well 15.

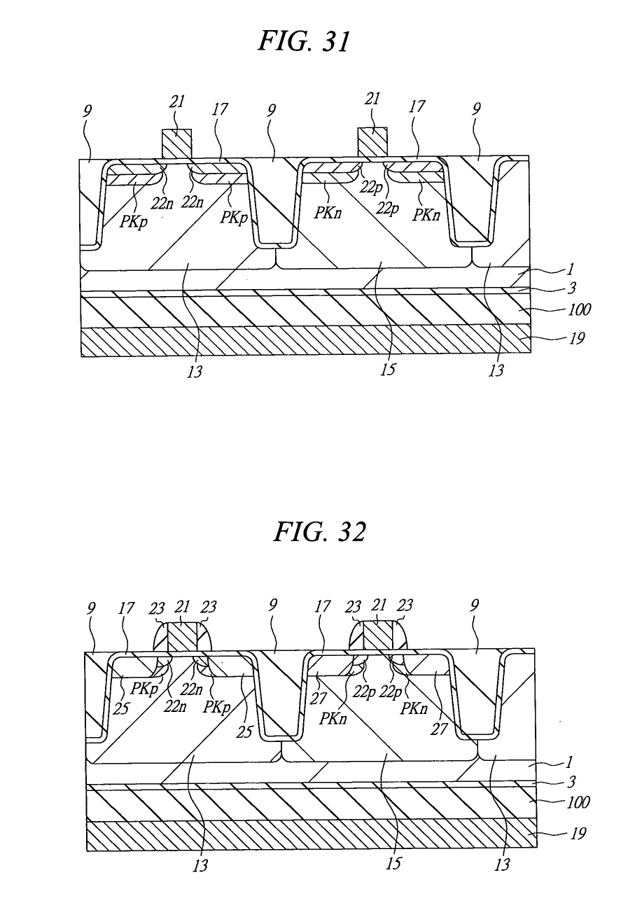

As shown in FIG. 31, the polysilicon film 19 is subjected to plasma etching, to form a gate electrode 21. The plasma etching is performed by using an etching apparatus of the single wafer processing type.

At this time, plasma is generated inside the etching apparatus. According to this embodiment, however, since the silicon oxide film 100 is formed on the back side of the semiconductor substrate, the influence of the electric charge with respect to the gate insulating film can be reduced, thereby improving the resisting pressure of the gate insulating film.

As shown in FIG. 32, a p-type pocket ion region PKp and an n⁻-type semiconductor region 22n are formed. Subsequently, an n-type pocket ion region PKn and an p⁻-type semiconductor region 22p are formed.

A sidewall spacer comprising a silicon nitride film 23 is formed on the sidewall of the gate electrode 21.

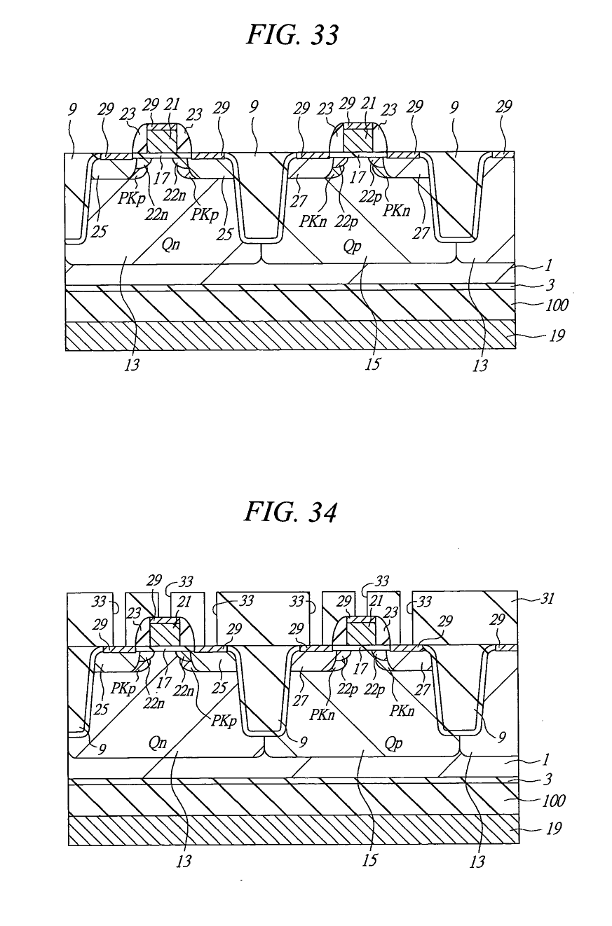

As shown in FIG. 33, an n⁺-type semiconductor region 25 (source and drain) and a p⁺-type semiconductor region 27 (source and drain) are then formed. A cobalt silicide layer 29 is then formed on the semiconductor substrate 1 and the gate electrode 21.

In the process up to here, an n-channel MISFET Qn and a p-channel MISFET Qp having the source and drain of a Lightly Doped Drain (LDD) structure are formed.

As shown in FIG. 34, a silicon oxide film 31 is deposited on the MISFET Qn and Qp as an interlayer insulating film by, for example, the high density plasma CVD method.

Contact holes 33 are then formed by etching the silicon oxide film 31.

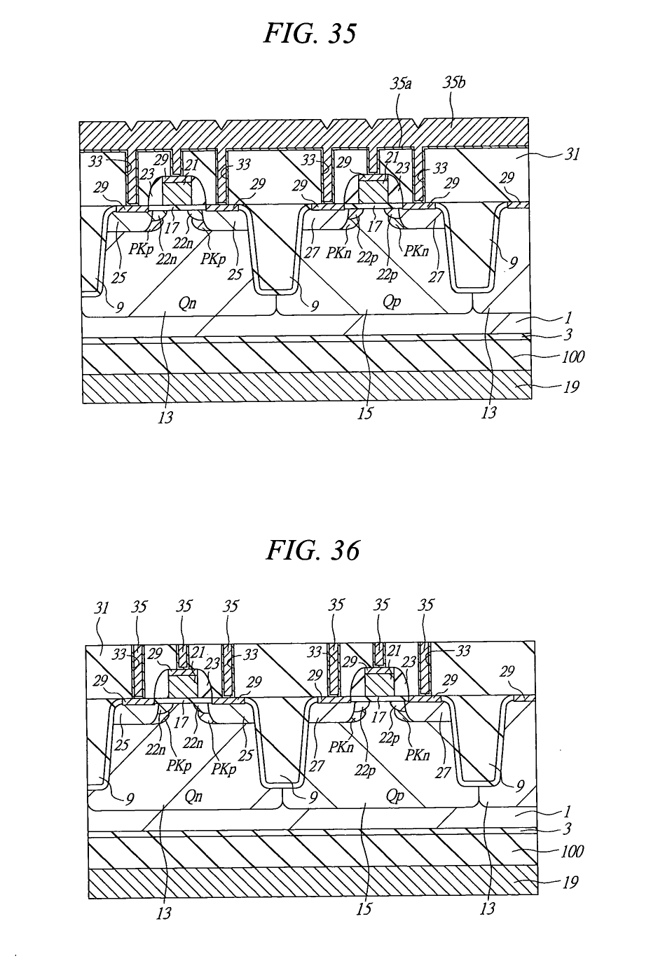

As shown in FIG. 35, a thin TiN film 35a is deposited, and the surface and the back side of the semiconductor substrate are cleaned. A W film 35b is then deposited by sputtering on the TiN film 35a.

As shown in FIG. 36, the W film 35b and the like are polished by the CMP method until the silicon oxide film 31 is exposed, thereby forming plugs 35 in the contact holes 33.

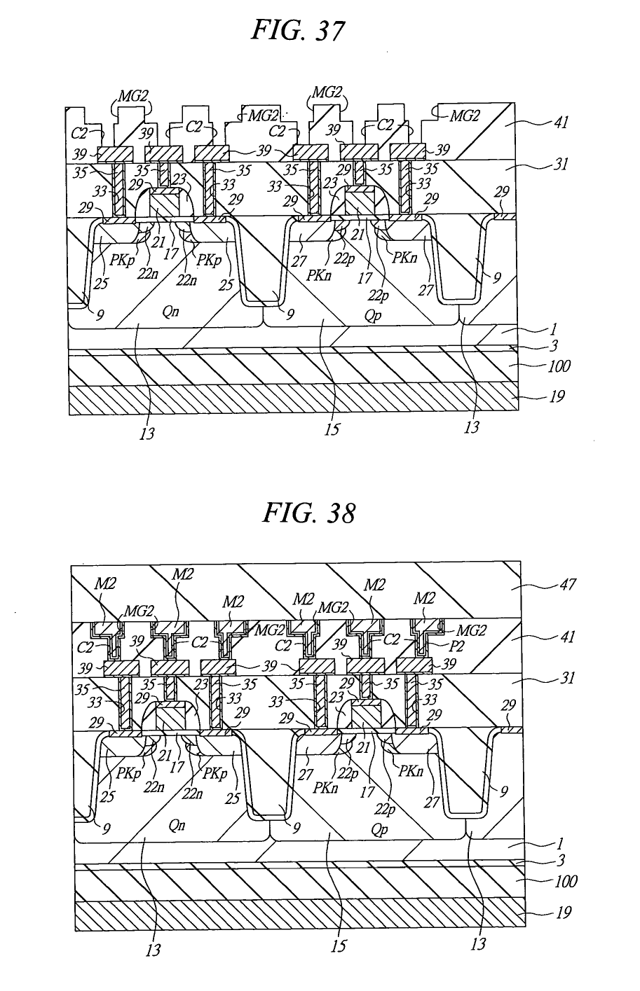

As shown in FIG. 37, a first layer wiring 39 comprising a TiN film 39a and a W film 39b is formed.

Thereafter, an interlayer insulating film 41 is formed on the silicon oxide film 31 including on the first layer wiring 39, and as explained in the second embodiment, wiring trenches MG2 and contact holes 22 are formed.

As shown in FIG. 38, a TiN film is formed as a barrier film and a Cu (copper) film is formed as a seed film, respectively on the semiconductor substrate, and a Cu film is further formed by the electrolytic plating method. The Cu film outside of the wiring trench MG2 and the contact hole C2 is polished by the CMP method, thereby to form a plug P2 and a second layer wiring M2.

Thereafter, by forming an insulating film 47 on the second layer wiring M2, and repeating the forming steps of the plugs and the wiring, a multi-layer wiring can be formed, but the description and illustration of the forming steps and mounting steps thereof are omitted.

According to this embodiment, since the silicon oxide film 100 is formed on the back side of the semiconductor substrate, even if electric charge is accumulated on the semiconductor substrate during the following processing (for example, plasma etching of the polysilicon film 19), the influence of the electric charge with respect to the gate insulating film can be reduced, thereby improving the resisting pressure of the gate insulating film. Further, since the back side of the semiconductor substrate is covered with the silicon oxide film 100 and the polysilicon film 19 at the time of forming the Cu film, contamination of the back side of the semiconductor substrate by copper can be prevented, and diffusion of Cu into the semiconductor substrate can be also prevented.

(Fourth Embodiment)

In the third embodiment, after the silicon oxide film 9 for element isolation has been deposited, the silicon oxide film 100 is formed on the back side of the semiconductor substrate, but as shown below, after the polysilicon film 19 has been deposited, the silicon oxide film 200 may be formed.

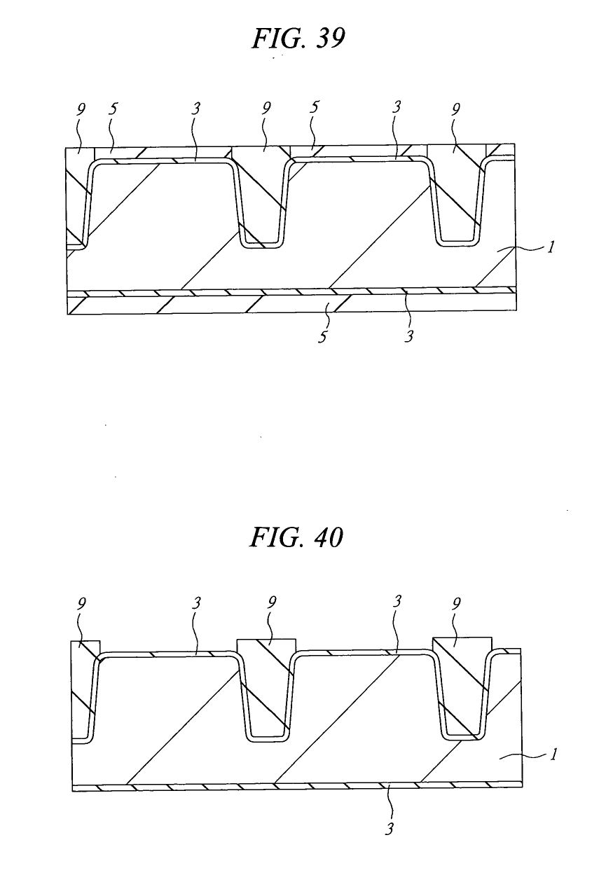

FIGS. 39 to 52 are sectional views of the main part of the semiconductor substrate, illustrating the manufacturing method of the semiconductor device according to the fourth embodiment. The manufacturing method of the semiconductor device in this embodiment will be described in order of steps. Detailed description for the same steps as in the first and the third embodiments is omitted.

As shown in FIG. 39, a pad oxide film 3 and a silicon nitride film 5 are deposited on the semiconductor substrate 1. At this time, the pad oxide film 3 and the silicon nitride film 5 are formed by using a batch-type apparatus, wherein the pad oxide film 3 and the silicon nitride film 5 are formed both on the surface and the back side of the semiconductor wafer W.

The processed silicon nitride film 5 and the pad oxide film 3 are used as a mask, to form trenches for element isolation, and after a thin oxide film has been formed on the surface of the trenches, a silicon oxide film 9 is deposited. Then, the silicon oxide film 9 on the trenches are polished by the CMP method, until the silicon nitride film 5 is exposed.

As shown in FIG. 40, the silicon nitride film 5 on the surface and the back side of the semiconductor substrate 1 is removed.

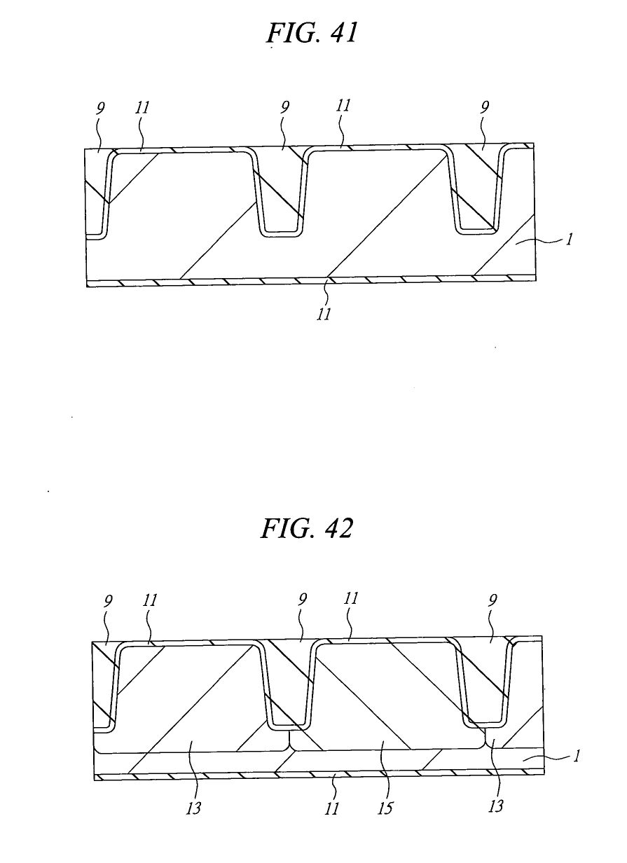

As shown in FIG. 41, after the pad oxide film 3 has been removed, a sacrificial oxide film 11 having a film thickness of about 11 nm is formed on the surface of the semiconductor substrate 1 by thermal oxidation. This sacrificial oxide film 11 is formed by using a batch-type thermal oxidation apparatus, and formed on the surface and the back side of the semiconductor wafer W.

As shown in FIG. 42, ion implantation for adjusting a threshold is performed, and then a p-type well 13 and an n-type well 15 are formed.

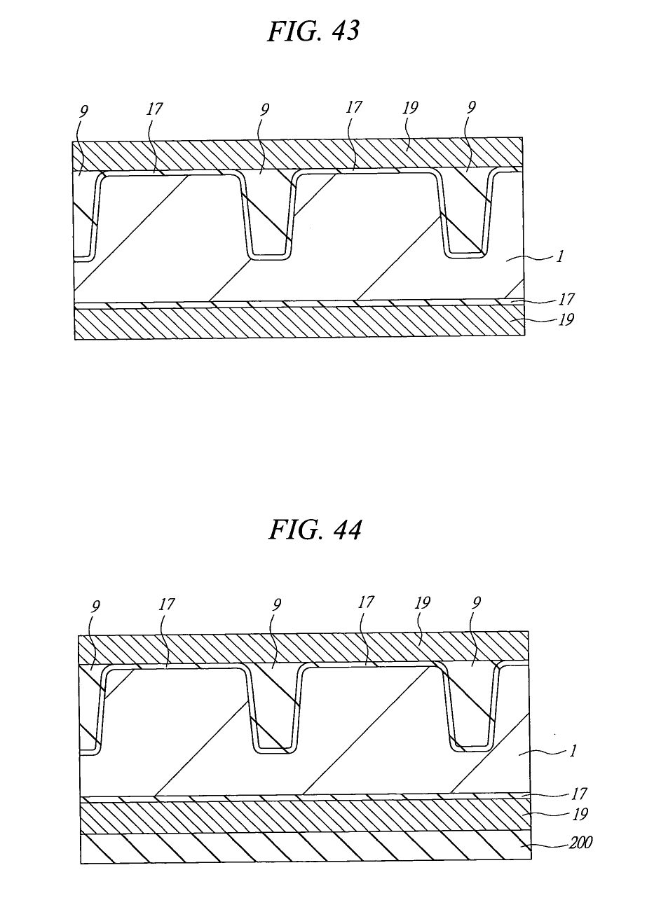

Thereafter, the surface of the semiconductor substrate 1 is cleaned, and after the sacrificial oxide film 11 on the surface and the back side of the semiconductor substrate 1 has been removed, as shown in FIG. 43, a gate insulating film 17 is formed on the surface of the semiconductor substrate 1, by thermal oxidation. This gate insulating film 17 is formed by using a batch-type heat treatment apparatus.

A polysilicon film 19 is deposited on the gate insulating film 17 by the CVD method. This polysilicon film 19 is formed by using a batch-type CVD apparatus, so that the back side thereof is also exposed to the raw material gas atmosphere. As a result, the polysilicon film 19 is formed both on the surface and the back side of the semiconductor wafer W.

The formation of the gate insulating film 17 may be performed by using a heat treat apparatus of the single wafer processing type, and the formation of the polysilicon film 19 may be performed by using a batch-type film forming apparatus. In this case, at the time of forming the gate insulating film 17, an insulating film is not formed on the back side of the wafer. At the time of forming the polysilicon film 19, the polysilicon film is directly formed on the back side of the wafer. By this polysilicon film, gettering can be enhanced as described below. Therefore, it is not necessary to form a polysilicon film for enhancing gettering, thereby enabling cost reduction of wafers.

As shown in FIG. 44, the silicon oxide film 200 is formed on the back side of the semiconductor substrate 1 as an insulating film by the CVD method. This silicon oxide film 200 is formed by using a CVD apparatus of the single wafer processing type, with the surface of the semiconductor wafer placed downward.

N-type impurities such as phosphorus are implanted into the polysilicon film 19 on the p-type well 13, and p-type impurities such as boron are implanted into the polysilicon film 19 on the n-type well 15.

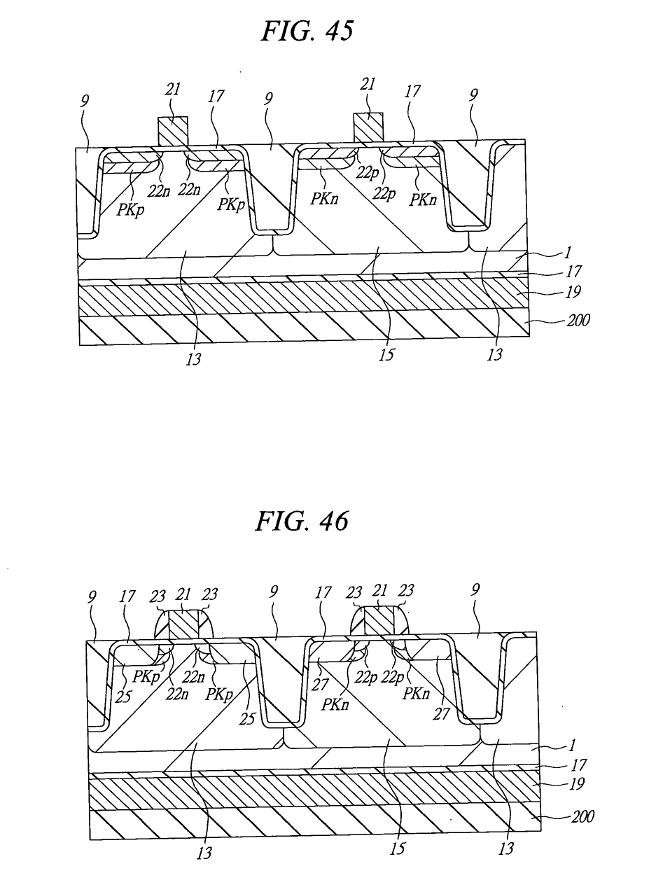

As shown in FIG. 45, the polysilicon film 19 is subjected to plasma etching, to form a gate electrode 21. The plasma etching is performed by using an etching apparatus of the single wafer processing type.

At this time, plasma is generated inside the etching apparatus. According to this embodiment, however, since the silicon oxide film 200 is formed on the back side of the semiconductor substrate, the influence of the electric charge with respect to the gate insulating film 17 can be reduced, thereby improving the resisting pressure of the gate insulating film.

As shown in FIG. 46, a p-type pocket ion region PKp and an n⁻-type region 22n are formed. Subsequently, an n-type pocket ion region PKn and an p⁻-type semiconductor region 22p are formed.

A sidewall spacer comprising a silicon nitride film 23 is formed on the sidewall of the gate electrode 21, and an n⁺-type semiconductor region 25 (source and drain) and a p⁺-type semiconductor region 27 (source and drain) are formed.

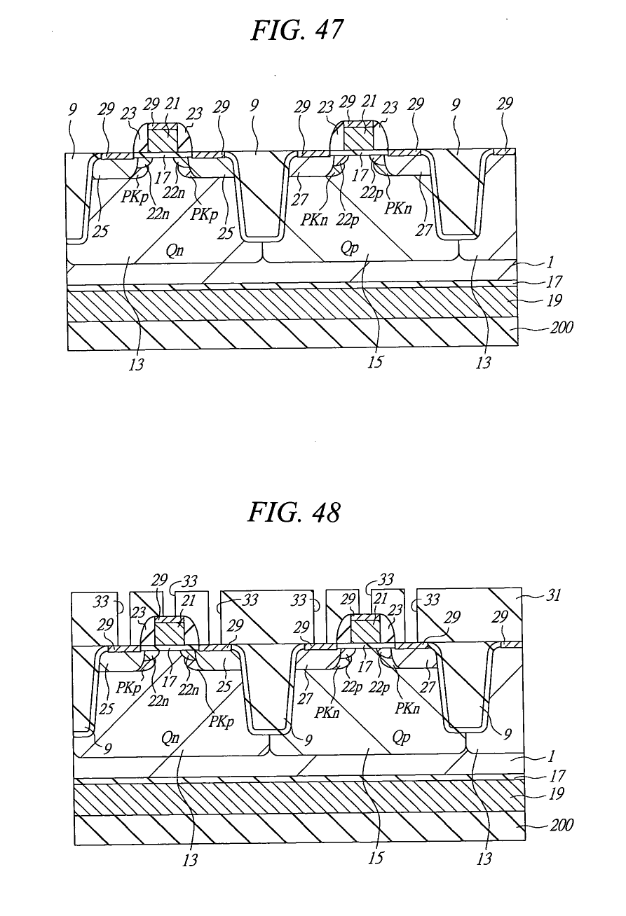

A cobalt silicide layer 29 is then formed on the semiconductor substrate 1 and the gate electrode 21, as shown in FIG. 47.

In the process up to here, an n-channel MISFET Qn and a p-channel MISFET Qp having the source and drain of a Lightly Doped Drain (LDD) structure are formed.

As shown in FIG. 48, a silicon oxide film 31 is deposited on the MISFET Qn and Qp as an interlayer insulating film by, for example, the high density plasma CVD method.

Contact holes 33 are then formed by etching the silicon oxide film 31.

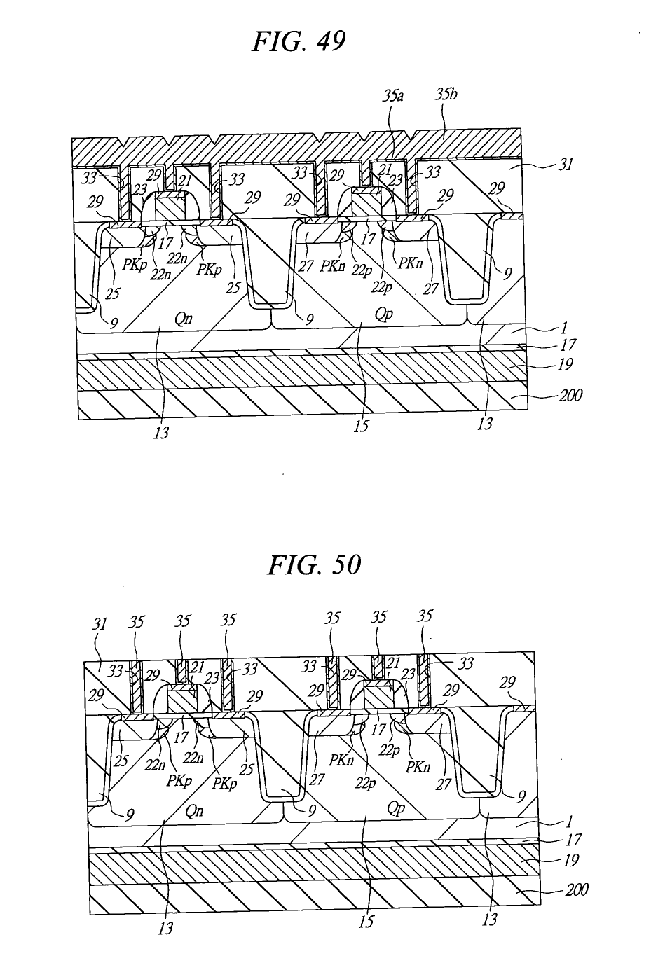

As shown in FIG. 49, a thin TiN film 35a is deposited, and the surface and the back side of the semiconductor substrate are cleaned. A W film 35b is then deposited by sputtering on the TiN film 35a.

As shown in FIG. 50, the W film 35b and the like are polished by the CMP method until the silicon oxide film 31 is exposed, thereby forming plugs 35 in the contact holes 33.

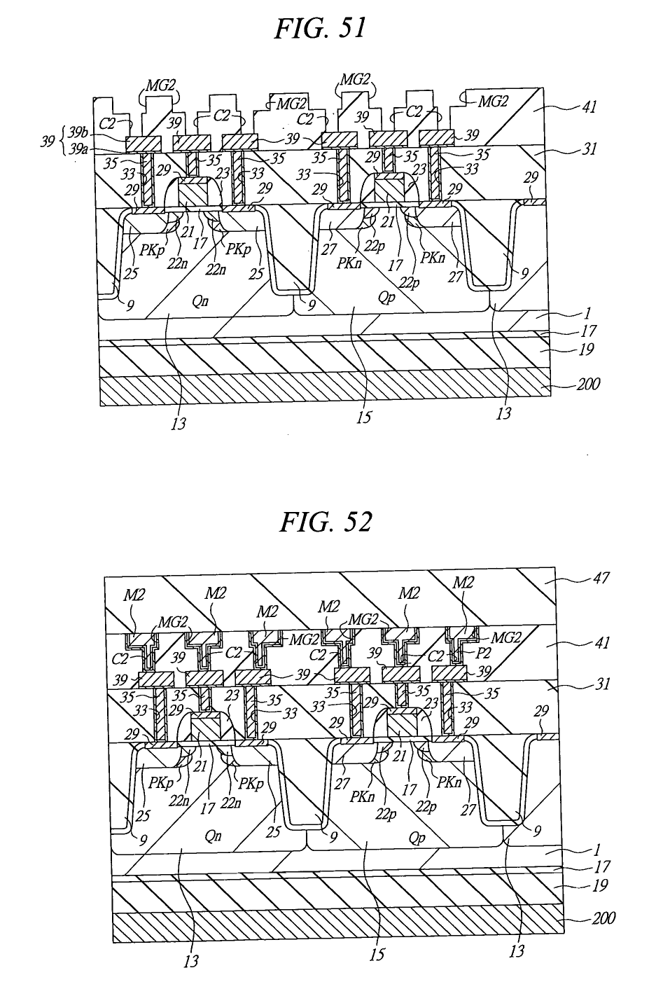

As shown in FIG. 51, a first layer wiring 39 comprising a TiN film 39a and a W film 39b is formed.

Thereafter, an interlayer insulating film 41 is formed on the silicon oxide film 31 including on the first layer wiring 39, and as explained in the second embodiment, wiring trenches MG2 and contact holes C2 are formed.

As shown in FIG. 52, a TiN film is formed as a barrier film and a Cu (copper) film is formed as a seed film, and a Cu film is further formed by the electrolytic plating method. The Cu film outside of the wiring trench MG2 and the contact hole C2 is polished by the CMP method, thereby to form a plug P2 and a second layer wiring M2.

Thereafter, by forming an insulating film 47 on the second layer wiring M2, and repeating the forming steps of the plugs and the wiring, a multi-layer wiring can be formed, but the description and illustration of the forming steps and mounting steps thereof are omitted.

According to this embodiment, since the silicon oxide film 200 is formed on the back side of the semiconductor substrate, even if electric charge is accumulated on the semiconductor substrate during the following processing (for example, plasma etching of the polysilicon film 19), the influence of the electric charge with respect to the gate insulating film can be reduced, thereby improving the resisting pressure of the gate insulating film.

Further, since the silicon oxide film 200 is formed on the back side of the semiconductor substrate, the back side of the semiconductor substrate becomes hydrophilic, so that the adhered material (particularly, metal material) is likely to be removed. Further, by using a cleaning solution that slightly etches the silicon oxide film formed on the back side of the semiconductor substrate, the material can be removed in a lift-off manner, thereby improving the cleaning efficiency.

Since the back side of the semiconductor substrate is covered with the polysilicon film 19 and the silicon oxide film 200 at the time of forming the Cu film, contamination of the back side of the semiconductor substrate by copper can be prevented, and diffusion of Cu into the semiconductor substrate can be also prevented.

It is as explained in the first embodiment that the forming process of the silicon oxide film (100, 200) is not limited to the time (timing) indicated in the third and the fourth embodiments.

Further, other than the silicon oxide film, a silicon nitride film or a laminated film thereof may be used, and the film thickness is preferably from 20 to 500 nm, as explained in the first embodiment.

The present invention has been specifically described based on the embodiments, but needless to say, the present invention is not limited to the embodiments, and can be changed variously without departing from the scope of the present invention.

Particularly, in the embodiments, the process for forming the semiconductor device in various production lines has been described, but the present invention is not limited to these production lines, and is widely applicable to a line in which an insulating film having a film thickness sufficient for improving the resisting pressure of the gate insulating film and the cleaning efficiency is not formed on the back side of the semiconductor substrate.

Further, a polysilicon film may be formed on the back side of the semiconductor substrate, in order to enhance gettering in the manufacturing process of the semiconductor device. The gettering refers to a function for capturing undesirable atoms and the like intruding into the semiconductor substrate, and for example, there is one which uses distortion on the interface between a single crystal silicon substrate and a polysilicon film.

Therefore, even after forming such a polysilicon film, the above-described effects can be exhibited by forming the insulating films (100, 200) described in the embodiments.

Since the polysilicon film for gettering is covered with the insulating film, the polysilicon on the back side of the semiconductor substrate is oxidized, and the oxide film and the polysilicon itself are etched. As a result, it can be prevented that the film thickness thereof is gradually reduced, or disappears.

The present invention is effective in the semiconductor manufacturing process in the single wafer processing, using semiconductor wafers having a diameter of about 300 mm (300±0.2 mm) or at least 300 mm.

The effects obtained by the representative inventions disclosed herein are as described below.

Before or after forming a gate insulating film in the manufacturing method of the semiconductor device, using mainly the single wafer processing, an insulating film is formed on the back side of the semiconductor substrate, thereby enabling prevention of deterioration in the resisting pressure of the gate insulating film. Moreover, the cleaning efficiency of the semiconductor wafer can be improved. As a result, the characteristics of the semiconductor device can be improved.

Further, before the cleaning step of the semiconductor wafer, which is performed after forming a metal film, an insulating film is formed on the back side of the semiconductor substrate, thereby improving the cleaning efficiency of the semiconductor wafer. As a result, the characteristics of the semiconductor device can be improved.

What is claimed is:

1. A manufacturing method of a semiconductor device, comprising the steps of:
(a) preparing a semiconductor wafer having a first principal plane on which an element is formed and a second principal plane opposite to said first principal plane;
b) forming a protective film on said second principal plane only of said semiconductor wafer;
(c) forming a gate insulating film on said first principal plane, after the step (b); and
(d) forming a conductor layer on said gate insulating film.

2. A manufacturing method of a semiconductor device according to claim 1, wherein said gate insulating film in the step (c) is formed by subjecting said first principal plane to thermal oxidation, with said gate insulating film of said semiconductor wafer mounted on a support in first apparatus.

3. A manufacturing method of a semiconductor device according to claim 1, wherein the step (d) comprises the steps of:
(d1) mounting said semiconductor wafer on a support in second apparatus, so that said second principal plane having said protective film formed thereon comes in contact with the support, and forming a conductive film on said gate insulating film by using a chemical vapor deposition method; and
(d2) etching said conductive film into a predetermined pattern.

4. A manufacturing method of a semiconductor device according to claim 3, wherein said etching is performed under a plasma atmosphere.

5. A manufacturing method of a semiconductor device according to claim 1, comprising a step of cleaning said semiconductor wafer, after the step (b).

6. A manufacturing method of a semiconductor device according to claim 1, further comprising the steps of:
forming a photoresist film pattern on said first principal plane of said semiconductor wafer, after the step (b) and before the step (c);
forming trenches for element isolation on said first principal plane, using said photoresist film pattern as a mask; and
removing said photoresist film pattern under a plasma atmosphere.

7. A manufacturing method of a semiconductor device according to claim 1, further comprising the steps of:
forming trenches for element isolation on said first principal plane, prior to the step (b), and
burying an insulating film in said trenches.

8. A manufacturing method of a semiconductor device according to claim 1, wherein said semiconductor wafer has a diameter of about 300 mm.

9. A manufacturing method of a semiconductor device according to claim 1, wherein said first principal plane and said second principal plane of said semiconductor wafer in the step (a) have been subjected to mirror finishing.

10. A manufacturing method of a semiconductor device, comprising the steps of:
(a) preparing a semiconductor wafer having a first principal plane on which an element is formed and a second principal plane opposite to said first principal plane;
(b) forming a gate insulating film on said first principal plane;
(c) forming a conductive film on said gate insulating film;
(d) after the step (c), forming a protective film on said second principal plane of said semiconductor wafer, with said first principal plane of said semiconductor wafer placed on a support in first apparatus; and
(e) etching said conductive film to form a gate electrode.

11. A manufacturing method of a semiconductor device according to claim 10, wherein said gate insulating film in the step (b) is formed by subjecting said first principal plane to thermal oxidation.

12. A manufacturing method of a semiconductor device according to claim 10, wherein after the step (c), said conductive film is selectively etched under a plasma atmosphere, to form said gate electrode.

13. A manufacturing method of a semiconductor device according to claim 10, comprising a step of cleaning said semiconductor wafer, after the step (b).

14. A manufacturing method of a semiconductor device according to claim 10, further comprising the steps of:
forming a photoresist film pattern on said first principal plane of said semiconductor wafer, before forming said protective film;
forming trenches for element isolation on said first principal plane, using said photoresist film pattern as a mask; and
removing said photoresist film pattern under a plasma atmosphere.

15. A manufacturing method of a semiconductor device according to claim 11, wherein said gate insulating film in the step (b) is formed by subjecting said first principal plane to thermal oxidation, and then to oxynitride processing.

16. A manufacturing method of a semiconductor device according to claim 10, wherein said semiconductor wafer has a diameter of not smaller than 300 mm.

17. A manufacturing method of a semiconductor device according to claim 10, wherein said first principal plane and said second principal plane of said semiconductor wafer have been subjected to mirror finishing.

18. A manufacturing method of a semiconductor device, comprising the steps of:
(a) preparing a semiconductor wafer having a first principal plane on which an element is formed and a second principal plane opposite to said first principal plane;
(b) forming a protective film on said second principal plane of said semiconductor wafer, with said first principal plane of said semiconductor wafer placed on a support in first apparatus;
(c) forming a metal or a metallic compound on said first principal plane, after the step (b); and
(d) cleaning said second principal plane of said semiconductor wafer, after the step (c).

19. A manufacturing method of a semiconductor device according to claim 18, wherein the step (c) is a step of forming a copper film on said first principal plane.

20. A manufacturing method of a semiconductor device according to claim 19, wherein said copper film is formed by plating.

21. A manufacturing method of a semiconductor device, comprising the steps of:
(a) preparing a semiconductor wafer having a first principal plane on which an element is formed and a second principal plane opposite to said first principal plane, and having a diameter of about 300 mm or not smaller than 300 mm;
(b) allowing a film to be formed so as to cover said second principal plane of said semiconductor wafer;
(c) mounting said semiconductor wafer on a susceptor in a single wafer processing unit so that the film on said second principal plane comes in contact with the susceptor; and
(d) processing said first principal plane of said semiconductor wafer by said single wafer processing unit.

22. A manufacturing method of a semiconductor device according to claim 21, wherein said first principal plane and said second principal plane of said semiconductor wafer have been subjected to mirror finishing.

23. A manufacturing method of a semiconductor device according to claim 22, wherein said mirror-finished first and second principal planes have a brightness of 80% or more.

24. A manufacturing method of a semiconductor device according to claim 22, wherein said mirror-finished first and second principal planes have a brightness of from 60% to 100% inclusive.

25. A manufacturing method of a semiconductor device according to claim 22, wherein said mirror-finished second principal planes is rougher than said first principal plane.

26. A manufacturing method of a semiconductor device according to claim 21, wherein said film is an insulating film formed by the CVD method.

27. A manufacturing method of a semiconductor device according to claim 26, wherein said insulating film includes an oxide film.

28. A manufacturing method of a semiconductor device, comprising the steps of:
(a) preparing a semiconductor wafer having a first principal plane and a second principal plane opposite to said first principal plane, and having a diameter of about 300 mm or not smaller than 300 mm;
(b) allowing an insulating film to be formed so as to cover said second principal plane of said semiconductor wafer;
(c) mounting said semiconductor wafer on a susceptor in a first single wafer processing unit so that the insulating film on said second principal plane comes in contact with the susceptor; and
(d) forming a gate insulating film on said first principal plane within said first single wafer processing unit;
(e) mounting the semiconductor wafer having said gate insulating film formed thereon on a susceptor in a second single wafer processing unit so that the insulating film on said second principal plane comes in contact with the susceptor;
(f) forming a metal or a semiconductor on said gate insulating film within said second single wafer processing unit;
(g) mounting the semiconductor wafer having the metal or semiconductor formed thereon on a susceptor in a third single wafer processing so that the insulating film on said second principal plane comes in contact with the susceptor;
(h) selectively etching the metal or semiconductor within said third single wafer processing unit to form a gate electrode;
(i) holding the semiconductor wafer having said gate electrode formed thereon within a fourth single wafer processing unit; and
(j) cleaning said semiconductor wafer within said fourth single wafer processing unit.
